(19) United States
(12) Patent Application Publication
(10) Pub. No.: US 2026/0136991 A1
(43) Pub. Date: May 14, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Tzu Jung TIEN, Hsinchu County (TW); Jen-Yuan CHANG, Hsinchu City (TW)

(21) Appl. No.: 18/946,075

(22) Filed: Nov. 13, 2024

(51) Int. Cl. H01L 25/16; G02B 6/12; G02B 6/124; G02B 6/13; G02B 6/42; H01L 21/762; H01L 23/00; H01L 23/29; H01L 23/31

(52) U.S. Cl. CPC H10W 90/00; G02B 6/124; G02B 6/13; G02B 6/4214; H10W 10/0145; H10W 10/17; H10W 74/117; H10W 74/473; G02B 2006/12107; H10W 74/10; H10W 90/792

(57) ABSTRACT

A semiconductor device includes a grating coupler and a dielectric plug adjacent to the grating coupler. The dielectric plug defines an optical signal path through which optical signals propagate to the grating coupler. To provide increased confinement of optical signals so as to reduce scattering and reduce crosstalk with other optical signals, a reflector structure is included around the perimeter of the dielectric plug. The reflector structure is formed of an optically reflective material such as one or more metal materials. The reflector structure may reduce the likelihood of scattering of the optical signal into the layers of the semiconductor device around the dielectric plug by reflecting the optical signal toward the grating coupler. Additionally and/or alternatively, the reflector structure may reduce the likelihood of other optical signals interfering with the optical signal by reflecting the other optical signals away from the grating coupler.

### BACKGROUND

A semiconductor device may include one or more photonics components that are configured to use optical signals for high-speed, high-bandwidth, and/or secure optical communication between integrated circuits and/or semiconductor dies of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example of a device package described herein.

FIGS. 2A-2D illustrate example top view shapes for a dielectric plug and an associated reflector structure described herein.

FIGS. 3A-3L are diagrams of an example implementation of forming an integrated circuit (IC) die described herein.

FIGS. 4A-4G are diagrams of an example implementation of forming a device package described herein.

FIGS. 5A and 5B are diagrams of an example implementation of a device package described herein.

FIG. 6 is a diagram of an example implementation of a device package described herein.

FIG. 7 is a diagram of an example implementation of a device package described herein.

FIG. 8 is a diagram of an example implementation of a device package described herein.

FIG. 9 is a diagram of an example implementation of a device package described herein.

FIG. 10 is a diagram of an example implementation of a device package described herein.

FIG. 11 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor device may include a grating coupler that is configured to receive optical signals (e.g., a laser signal or incident light) and direct the optical signals toward a photodetector of the semiconductor device. The photodetector may convert the optical signals to electrical signals that may be processed by the integrated circuit (IC) devices of the semiconductor device.

In some cases, interference with reception of an optical signal at a grating coupler of a semiconductor device may occur for various reasons. For example, a semiconductor device may include a plurality of grating couplers positioned near each other, and optical signals directed to these grating couplers can interfere with each other (referred to as optical crosstalk), which can lead to increased conversion errors when converting the optical signals to electrical signals. The grating couplers may be spaced further apart to reduce the likelihood of optical crosstalk; however, this increases the lateral size of the semiconductor device. As another example, an optical signal may propagate through a plurality of layers before reaching a grating coupler of a semiconductor device, and the longer the distance traveled through the layers, the greater the amount of scattering of the optical signal can occur.

In some implementations described herein, a semiconductor device includes a grating coupler and a dielectric plug adjacent to the grating coupler. The dielectric plug defines an optical signal path through which optical signals propagate to the grating coupler. To provide increased confinement of optical signals so as to reduce scattering and reduce crosstalk with other optical signals, a reflector structure is included around the perimeter of the dielectric plug. The reflector structure is formed of an optically reflective material such as one or more metal materials. The reflector structure may reduce the likelihood of scattering of the optical signal into the layers of the semiconductor device around the dielectric plug by reflecting the optical signal toward the grating coupler. Additionally and/or alternatively, the reflector structure may reduce the likelihood of other optical signals interfering with the optical signal by reflecting the other optical signals away from the grating coupler. In this way, the reflector structure reduces scattering of and/or interference with the optical signal, which may reduce the likelihood of and/or the rate of conversion errors when converting the optical signal to an electrical signal.

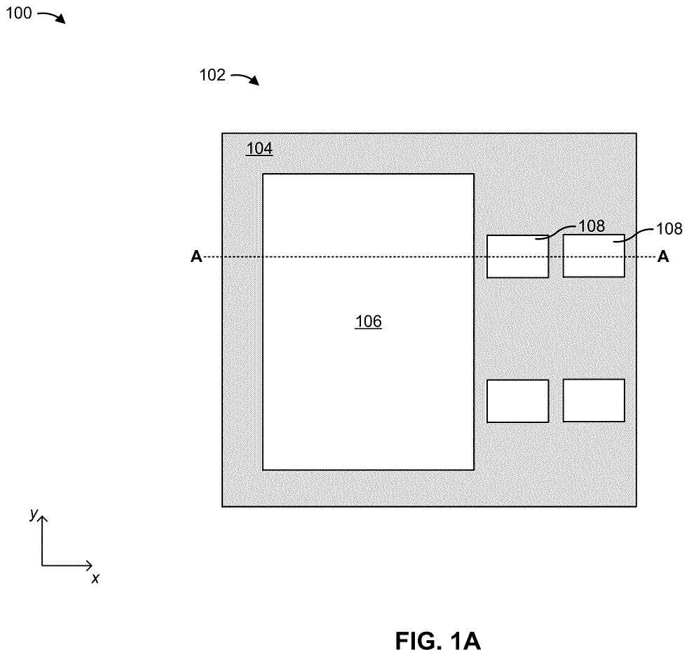

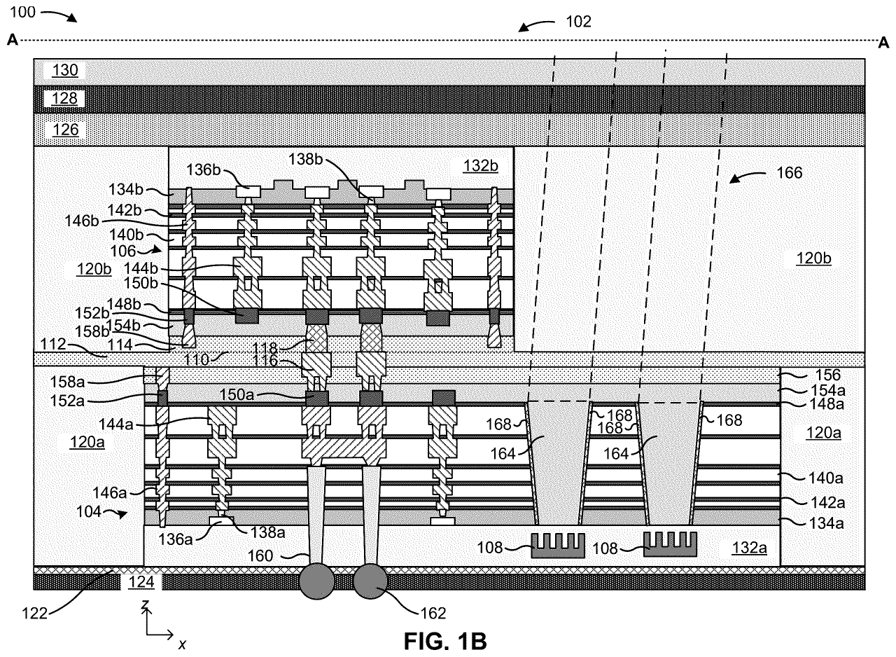

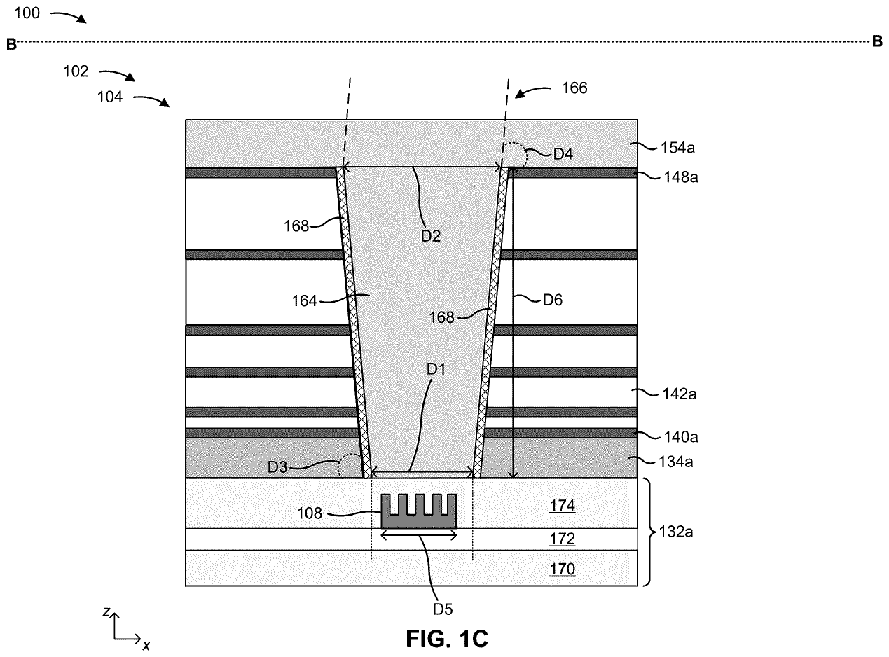

FIGS. 1A-1C are diagrams of an example 100 of a device package 102 described herein. The device package 102 includes a packaged semiconductor device that includes a plurality of active IC dies or chips. The plurality of active IC dies may be vertically arranged and/or stacked in the device package 102 using three-dimensional (3D) packaging techniques such as direct bonding.

FIG. 1A illustrates a top view of the device package 102. As shown in FIG. 1A, the device package 102 may be a semiconductor device that includes an IC die 104 and an IC die 106 bonded to the IC die 104. The IC die 106 is included on the IC die 104 such that the IC dies 104 and 106 are stacked and vertically arranged in a z-direction in the device package 102.

The IC die 104 is semiconductor device that includes one or more photonics components such as grating couplers, waveguides, photodiodes, splitters, polarizers, optical modulators, optical resonators, and/or edge couplers, among other examples. The IC die 104 may be configured to receive and/or transmit optical signals, process optical signals, and/or to perform other functions associated with optical signals. In some implementations, the IC die 104 is configured to convert optical signals to electrical signals, and/or to convert electrical signals to optical signals.

The IC die 106 may include active integrated circuits of the device package 102 and may be configured perform various processing functions of the device package 102. For example, the IC die 106 may be configured to process electrical signals that are converted from optical signals by the IC die 104. As another example, the IC die 106 may generate electrical signals that are to be converted to optical signals by the IC die 104. Examples for the IC die 104 includes a logic IC die, a memory IC die, a high-bandwidth memory (HBM) IC die, an input/output (I/O) die, a system-on-chip (SoC) IC die, a dynamic random access memory (DRAM) IC die, a complementary metal-oxide-semiconductor (CMOS) image sensor IC die, a silicon photonics IC die, a central processing unit (CPU) IC die, a graphics processing unit (GPU) IC die, a digital signal processing (DSP) IC die, an application specific integrated circuit (ASIC) IC die, and/or another type of active IC die.

As further shown in FIG. 1A, the top view area of the IC die 106 may be different from the top view area of the IC die 104. For example, the top view size of the IC die 104 (e.g., the size of the x-y area occupied by the IC die 104) may be greater than the top view size of the IC die 106 (e.g., the size of the x-y area occupied by the IC die 106). This enables one or more grating couplers 108 to be positioned in the IC die 104 such that an unobstructed light propagation path is provided laterally adjacent to the IC die 106 for the grating couplers 108.

FIG. 1B illustrates a cross-section view of the device package 102 along the line A-A in FIG. 1A. Thus, the cross-section view illustrated in FIG. 1B includes the IC die 104 and the IC die 106 over and/or on the IC die 104.

As shown in FIG. 1B, the IC dies 104 and 106 are bonded together at a bonding interface 110. The IC dies 104 and 106 may be directly bonded (e.g., without an intervening interposer or another intervening structure) such that the IC dies 104 and 106 are stacked and vertically arranged in the z-direction in the device package 102.

The bonding interface 110 may include dielectric-to dielectric bonds between a dielectric layer (or bonding film) 112 of the IC die 104 and a bonding dielectric layer 114 of the IC die 106. The bonding dielectric layers 112 and 114 each include one or more types of dielectric materials such as a silicon oxide (SiOₓ) (e.g., silicon dioxide (SiO₂)) and/or another type of dielectric bonding material.

Additionally and/or alternatively, the bonding interface 110 may include metal-to-metal bonds between bonding structures 116 of the IC die 104 and bonding structures 118 of the IC die 106. The bonding structures 116 and 118 may each include bonding vias, bonding pads, and/or other types of bonding structures, and may each include one or more metals such as tungsten (W), cobalt (Co), ruthenium (Ru), titanium (Ti), aluminum (Al), and/or gold (Au), among other electrically conductive materials.

As further shown in FIG. 1B, the areas around the sides of the IC die 104 are filled with a dielectric fill layer 120a (e.g., a filler material layer) such that the dielectric fill layer 120a surrounds the IC die 104, and the areas around the sides of the IC die 106 are filled with a dielectric fill layer 120b (e.g., a filler material layer) such that the dielectric fill layer 120b surrounds the IC die 106. The dielectric fill layers 120a and 120b may each include one or more dielectric materials such as a silicon oxide (SiOₓ) (e.g., silicon dioxide (SiO₂)), silicon oxynitride (SiON), and/or another type of dielectric material. The dielectric fill layers 120a and 120b may provide increased stability and electrical isolation for the IC dies 104 and 106.

The device package 102 includes a plurality of passivation layers, including passivation layers 122 and 124 over and/or on a bottom side of the device package 102, and passivation layers 126, 128, and 130 over and/or on a top side of the device package 102, among other examples. In some implementations, the passivation layers 122, 124, 126, 128, and 130 may each include various types of electrically insulating materials, such as a silicon nitride (SiₓN_{y}), an undoped silicate glass (USG), a silicon oxide (SiOₓ) (e.g., silicon dioxide (SiO₂)), and/or another type of passivation material.

The IC dies 104 and 106 may each include a substrate (e.g., substrate 132a in the IC die 104 and substrate 132b in the IC die 106). The substrates 132a and 132b may each include a silicon (Si) substrate, a substrate formed of a material including silicon, a III-V compound semiconductor material substrate such as gallium arsenide (GaAs), a silicon on insulator (SOI) substrate, or another type of semiconductor substrate.

The IC dies 104 and 106 may each include a plurality of stacked layers, including an interlayer dielectric (ILD) layer (e.g., an ILD layer 134a on the substrate 132a and an ILD layer 134b on the substrate 132b). The ILD layers 134a and 134b may each include a silicon nitride (SiₓN_{y}), an oxide (e.g., a silicon oxide (SiOₓ) and/or another oxide material), and/or another type of dielectric material.

The IC dies 104 and 106 may each include IC devices (e.g., IC devices 136a in the substrate 132a and/or in the ILD layer 134a, IC devices 136b in the substrate 132b and/or in the ILD layer 134b). The IC devices 136a of the IC die 104 may include photonic devices such as modulators, photodetectors, resonators and/or waveguides, among other examples. The grating couplers 108 may also be included in the substrate 132a of the IC die 104. Thus, the IC die 104 may be referred to as a photonic integrated circuit (PIC) die.

The grating couplers 108 may each include a plurality of gratings. In some implementations, the gratings may be periodic, and the periodicity of the gratings may be selected to achieve diffraction of one or more wavelengths of optical signals. In some implementations, the periodicity of the gratings may be selected based on the wavelength(s) that are to be used for optical communication, may be selected based on the wavelength(s) that are to be used for wavelength division multiplexing (WDM), and/or for another purpose.

The grating couplers 108 may be located in a portion or region of the IC die 104 that extends laterally outward from the IC die 106. This provides an unobstructed light propagation path for optical signals to the grating couplers 108. The grating couplers 108 may be confirmed configured to redirect the optical signals toward the IC devices 136a for processing (e.g., demodulation, filtering, optical-to-electric conversion).

In some implementations, a grating coupler 108 is formed of a semiconductor material such as silicon (Si), germanium (Ge), and/or silicon germanium (SiGe), among other examples. In some implementations, a grating coupler 108 is formed of a dielectric material such as silicon nitride (SiₓN_{y} such as Si₃N₄) and/or silicon oxide (SiOₓ such as SiO₂), among other examples. In some implementations, a grating coupler 108 is a hybrid grating coupler structure that includes a dual-layer structure having a dielectric portion and a semiconductor portion.

The IC devices 136b of the IC die 106 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receivers, optical circuits, and/or other types of front end semiconductor devices. The IC devices 136b may receive electrical signals from the IC devices 136a of the IC die 104 and may be configured to process those electrical signals. Thus, the IC die 106 may be referred to as an electronic IC (EIC) die.

The IC dies 104 and 106 may each include contacts (e.g., contacts 138a, contacts 138b) that are electrically coupled with the IC devices. The contacts 138a may extend through the ILD layer 134a and may be electrically coupled with the IC devices 136a, and the contacts 138b may extend through the ILD layer 134b and may be electrically coupled with the IC devices 136b.

The contacts 138a and 138b may include vias, plugs, and/or another type of elongated electrically conductive structures. The contacts 138a and 138b may include tungsten (W), cobalt (Co), ruthenium (Ru), titanium (Ti), aluminum (Al), and/or gold (Au), among other electrically conductive materials.

The IC dies 104 and 106 may each include a plurality of dielectric layers that are arranged in an alternating manner in the z-direction in the device package 102. For example, the IC die 104 may include a plurality of alternating ILD layers 140a and etch stop layers (ESLs) 142a. The IC die 104 may include a plurality of conductive structures 144a in the ILD layers 140a and ESLs 142a. The substrate 132a, the ILD layer 134a, the IC devices 136a (and/or the grating couplers 108), and the contacts 138a may correspond to a device layer or front end of line (FEOL) region of the IC die 104, and the ILD layers 140a, the ESLs 142a, and the conductive structures 144a may correspond to an interconnect layer or back end of line (BEOL) region of the IC die 104.

Similarly, the IC die 106 may include a plurality of alternating ILD layers 140b and ESLs 142b. The IC die 106 may include a plurality of conductive structures 144b in the ILD layers 140b and ESLs 142b. The substrate 132b, the ILD layer 134b, the IC devices 136b, and the contacts 138b may correspond to a device layer or FEOL region of the IC die 106, and the ILD layers 140b, the ESLs 142b, and the conductive structures 144b may correspond to an interconnect layer or BEOL region of the IC die 106.

The ILD layers 140a and 140b may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 140a or 140b includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples. The ESLs 142a and 142b may each include a silicon nitride (SiₓN_{y}), silicon carbide (SiC), silicon oxynitride (SiON), and/or another suitable dielectric material.

The conductive structures 144a and 144b provide electrical routing that enables signals and/or power to be provided to and/or from the IC devices 136a and/or 136b. The conductive structures 144a and 144b may include a combination of trenches, metallization layers, conductive traces, vias, interconnects, and/or other types of conductive structures. The conductive structures 144a and 144b may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The IC die 104 may further include a seal ring structure 146a around the conductive structures 144a to protect the IC die 104 from physical and/or electrical damage during a dicing operation to cut the IC die 104 from a wafer. The seal ring structure 146a may further provide protection from humidity ingress and other contaminants. The IC die 106 may similarly include a seal ring structure 146b around the conductive structures 144b to protect the IC die 106 from physical and/or electrical damage during a dicing operation to cut the IC die 106 from a wafer. The seal ring structure 146b may further provide protection from humidity ingress and other contaminants.

The IC die 104 may include a passivation layers 148a over and/or on the plurality of alternating dielectric layers (e.g., the ILD layers 140a and the ESLs 142a) to passivate the interconnect layer of the IC die 104. Similarly, the IC die 106 may include a passivation layer 148b over and/or on the plurality of alternating dielectric layers (e.g., the ILD layers 140b and the ESLs 142b) to passivate the interconnect layer of the IC die 106.

Metal pad structures 150a may be included over and/or on the conductive structures 144a, and metal pad structures 152a may be included over and/or on the seal ring structure 146a. Metal pad structures 150b may be included over and/or on the conductive structures 144b, and metal pad structures 152b may be included over and/or on the seal ring structure 146b. The metal pad structures 150a and 152a may extend through the passivation layer 148a, another passivation layer 154a may be included over the metal pad structures 150a and 152a, and a dielectric layer 156 may be included on the passivation layer 154a. The metal pad structures 150b and 152b may extend through the passivation layer 148b, and another passivation layer 154b may be included over the metal pad structures 150b and 152b.

The passivation layers 148a, 148b, 154a, 154b and the dielectric layer 156 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), a silicon nitride (SiₓN_{y}), silicon carbide (SiC), silicon oxynitride (SiON), and/or another suitable dielectric material. In some implementations, a passivation layer 148a, 148b, 154a, and/or 154b, and/or the dielectric layer 156, includes an ELK dielectric material having a dielectric constant that is less than approximately 2.5.

The metal pad structures 150a, 152a, 150b, and/or 152b may each include aluminum (Al), aluminum copper (AlCu), copper (Cu), and/or another conductive material. The metal pad structures 150a and 152a may correspond to a redistribution layer (RDL) of the IC die 104, and the metal pad structures 150b and 152b may correspond to an RDL of the IC die 106. In some implementations, the seal ring structures 146a and 146b may further include bonding pads 158a and 158b, respectively. Alternatively, the bonding pads 158a and/or 158b may be omitted. The bonding pads 158a and 158b may each include tungsten (W), cobalt (Co), ruthenium (Ru), titanium (Ti), aluminum (Al), copper (Cu), gold (Au), and/or a combination thereof, among other examples of electrically conductive materials.

In some implementations, the IC die 104 further includes a through-substrate interconnect structure 160 that extends through the substrate 132a of the IC die 104. The through-substrate interconnect structure 160 may include a through substrate via (TSV) or another type of through-substrate interconnect. The through-substrate interconnect structure 160 may electrically connect the conductive structures 144a of the IC die 104 to connection structures 162 of the device package 102. The through-substrate interconnect structure 160 includes a conductive material such as tungsten (W), cobalt (Co), ruthenium (Ru), titanium (Ti), aluminum (Al), copper (Cu), gold (Au), and/or a combination thereof, among other examples of conductive materials. The through-substrate interconnect structure 160 may include a via, a pillar, a column, and/or another type of elongated conductive structure that extends between a front side of the substrate 132a of the IC die 104 (the side of the substrate 132a on which the conductive structures 144a are included) and a back side of the substrate 132b of the IC die 104 vertically opposing the front side.

The connection structures 162 may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures that enable the device package 102 to be connected to a substrate or a socket, among other examples.

As further shown in FIG. 1B, a dielectric plug 164 may be included above and/or over a grating coupler 108 in the IC die 104. A dielectric plug 164 may extend through the passivation layer 148a, the ILD layers 140a, the ESLs 142a, and/or the ILD layer 134a. In some implementations, a dielectric plug 164 partially extends into the substrate 132a. In some implementations, a dielectric plug 164 extends into, but not through, the ILD layer 134a. In these implementations, a portion of the ILD layer 134a remains between the bottom of the dielectric plug 164 and the substrate 132a. A dielectric plug 164 may provide an optical transmission path for incident light 166 (e.g., optical signals) to propagate through the IC die 104 to an underlying grating coupler 108. The dielectric plug 164 may include one or more dielectric materials such as a silicon oxide (SiOₓ), a silicon nitride (SiₓN_{y}), silicon carbide (SiC), silicon oxynitride (SiON), and/or another suitable dielectric material. In some implementations, the dielectric plug 164 includes a polymer material or a molding compound.

As further shown in FIG. 1B, reflector structures 168 are included on the sidewalls of the dielectric plugs 164. A reflector structure 168 may laterally surround a dielectric plug 164 such that the reflector structure 168 is a closed-loop conformal layer that extends fully around the perimeter of the dielectric plug 164. A reflector structure 168 may include a thin film layer (e.g., a conformal metal thin film layer) that includes one or more reflective materials so that the reflector structure 168 reflects incident light 166 in the dielectric plug 164 toward the underlying grating coupler 108 as opposed to the incident light 166 diffusing or scattering into the surrounding dielectric layers. Moreover, the reflective material of a reflector structure 168 enables the reflector structure 168 to block unwanted incident light 166 that is intended for an adjacent grating coupler 108, thereby reducing optical crosstalk in the IC die 104. Examples of such materials include tantalum (Ta), titanium (Ti), aluminum (Al), copper (Cu), tungsten (W), another reflective metal, tantalum nitride (TaN), titanium nitride (TiN), and/or another reflective material.

In some implementations, a liner is included between the reflector structures 168 and the surrounding dielectric layers. The liner may include a barrier liner, an adhesion liner, and/or another type of liner, and may include materials such as tantalum nitride (TaN) and/or titanium nitride (TiN), among other examples.

FIG. 1C illustrates a detailed view of a dielectric plug 164 over a grating coupler 108 and an associated reflector structure 168. As shown in FIG. 1C, in some implementations, the substrate 132a of the IC die 104 includes an SOI substrate that includes a semiconductor layer 170 and a buried dielectric layer (e.g., a buried oxide (BOX) layer) 172 on the semiconductor layer 170. Another semiconductor layer may originally have been included on the buried dielectric layer 172 and subsequently etched to define the grating couplers 108. Another dielectric layer 174 may be formed around and/or over the grating couplers 108 above the buried dielectric layer 172. Alternatively, the semiconductor layer 170 may be omitted from the IC die 104 in that the semiconductor layer 170 may be removed during back side processing of the IC die 104 after formation of the grating couplers 108.

FIG. 1C further illustrates various example dimensions of the IC die 104. As shown in FIG. 1C, an example dimension D1 includes a bottom lateral width of the dielectric plug 164, and another example dimension D2 includes a top lateral width of the dielectric plug 164. In some implementations, the dimension D2 is greater than the dimension D1 such that the sidewalls of the dielectric plug 164 (and the reflector structure 168 on the sidewalls of the dielectric plug 164) are non-vertical and are instead oriented at an angle (indicated in FIG. 1C as dimension D3) that is less than 90 degrees. This results in the dielectric plug 164 having a tapered cross-sectional profile where the lateral width of the dielectric plug 164 decreases from the top of the dielectric plug 164 to the bottom of the dielectric plug 164. Moreover, this results in the reflector structure 168 being angled away from the grating coupler 108 from the bottom for the bottom of the reflector structure 168 to the top of the reflector structure 168, which enables the reflector structure 168 to more effectively capture and redirect optical signals toward the grating coupler 108. However, in other implementations, the angle of the sidewalls of the dielectric plug 164 and of the reflector structure 168 may be approximately 90 degrees.

In some implementations, the outward angle (dimension D3) of the sidewalls of the dielectric plug 164 and of the reflector structure 168 is based on an angle (indicated in FIG. 1C as dimension D4) of incident light 166 that is to be received at the grating coupler 108. For example, the angle of incident light 166 (e.g., relative to the surface of the substrate 132a) may be a non-90 degree angle, and the outward angle (dimension D3) of the sidewalls of the dielectric plug 164 and of the reflector structure 168 may be approximately equal to the angle of incident light 166. However, other angles for the outward angle (dimension D3) of the sidewalls of the dielectric plug 164 and of the reflector structure 168 are within the scope of the present disclosure.

The bottom width (dimension D1) of the dielectric plug 164 may be based on a size of the underlying grating coupler 108. For example, the bottom width (dimension D1) of the dielectric plug 164 may be based on a lateral width (indicated in FIG. 1C as dimension D5) of the underlying grating coupler 108. In particular, the bottom width (dimension D1) of the dielectric plug 164 may be sized so that the underlying grating coupler 108 fits within the perimeter of the bottom of the dielectric plug 164 so that the light propagation path for incident light 166 to the grating coupler 108 is not obscured by the reflector structure 168 surrounding the dielectric plug 164. Thus, the bottom width of the dielectric plug 164 may be greater than the lateral width of the grating coupler 108 (e.g., D1>D5). However, other sizes for the bottom width of the dielectric plug 164 are within the scope of the present disclosure.

As further shown in FIG. 1C, the dielectric plug 164 may have a vertical (z-direction) height indicated in FIG. 1C as dimension D6. In some implementations, the dimension bottom width (dimension D1) of the dielectric plug 164 and the top width (dimension D2) of the dielectric plug 164 may be based on the outward angle (dimension D3) of the sidewalls of the dielectric plug 164 and of the reflector structure 168, may be based on the angle (dimension D4) of incident light 166, and/or may be based on the vertical (z-direction) height (dimension D6) of the dielectric plug 164, among other examples.

As indicated above, FIGS. 1A-1C are provided as an example. Other examples may differ from what is described with regard to FIGS. 1A-1C.

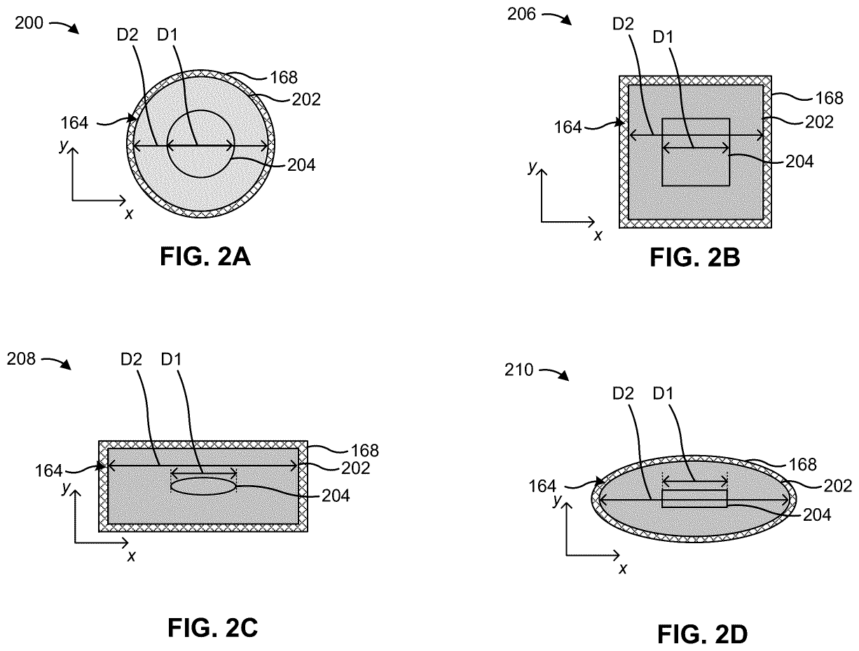

FIGS. 2A-2D illustrate example top view shapes for a dielectric plug 164 and an associated reflector structure 168 described herein. While FIGS. 2A-2D provide various examples, other example top view shapes for dielectric plugs 164 and/or for reflector structures 168 are within the scope of the present disclosure. Moreover, the IC die 104 may include a plurality of dielectric plugs 164 and/or reflector structures 168 that have a combination of example top view shapes.

As shown in FIG. 2A, an example top view shape 200 includes an approximate circle top view shape in which a top 202 of the dielectric plug 164 and a bottom 204 of the dielectric plug 164 both have an approximate circle top view shape. The width (dimension D1) of the bottom 204 of the dielectric plug 164 may be less than the width (dimension D2) of the top 202 of the dielectric plug 164. The reflector structure 168 may conform to the top view shape 200 and may have a closed-loop hollow circle top view shape (or ring shape).

As shown in FIG. 2B, an example top view shape 206 includes a polygon top view shape in which a top 202 of the dielectric plug 164 and a bottom 204 of the dielectric plug 164 both have an approximate square top view shape. Alternatively, the top 202 and/or the bottom 204 of the dielectric plug 164 may have another polygon top view shape, such as a rectangle top view shape, a triangle top view shape, and/or a hexagon top view shape, among other examples. The width (dimension D1) of the bottom 204 of the dielectric plug 164 may be less than the width (dimension D2) of the top 202 of the dielectric plug 164. The reflector structure 168 may conform to the top view shape 200 and may have a closed-loop hollow polygon top view shape (e.g., a hollow square shape, a hollow rectangle shape).

As shown in FIGS. 2C and 2D, a dielectric plug 164 may have a compound top view shape. The associated reflector structure 168 around the dielectric plug 164 may conform to the compound top view shape.

For example, a top view shape 208 illustrated in FIG. 2C includes a polygon top view shape at the top 202 of the dielectric plug 164 and an approximate circle top view shape at the bottom 204 of the dielectric plug 164. The shape of the dielectric plug 164 may transition between the polygon top view shape at the top 202 of the dielectric plug 164 and the approximate circle top view shape at the bottom 204 of the dielectric plug 164 along a height of the dielectric plug 164. The width (dimension D1) of the bottom 204 of the dielectric plug 164 may be less than the width (dimension D2) of the top 202 of the dielectric plug 164.

As another example, a top view shape 210 illustrated in FIG. 2D includes an approximate circle top view shape at the top 202 of the dielectric plug 164 and a polygon top view shape at the bottom 204 of the dielectric plug 164. The shape of the dielectric plug 164 may transition between the approximate circle top view shape at the top 202 of the dielectric plug 164 and the polygon top view shape at the bottom 204 of the dielectric plug 164 along a height of the dielectric plug 164. The width (dimension D1) of the bottom 204 of the dielectric plug 164 may be less than the width (dimension D2) of the top 202 of the dielectric plug 164.

As indicated above, FIGS. 2A-2D are provided as examples. Other examples may differ from what is described with regard to FIGS. 2A-2D.

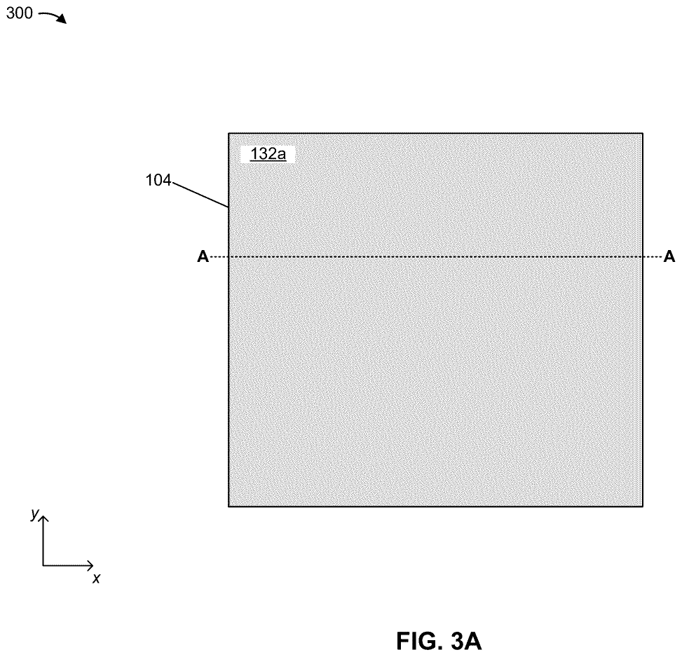

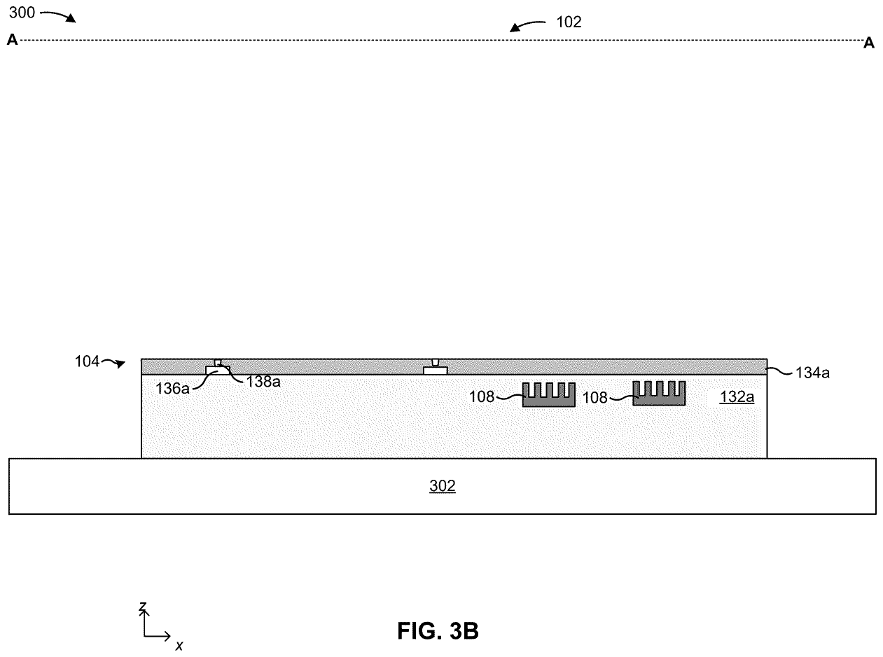

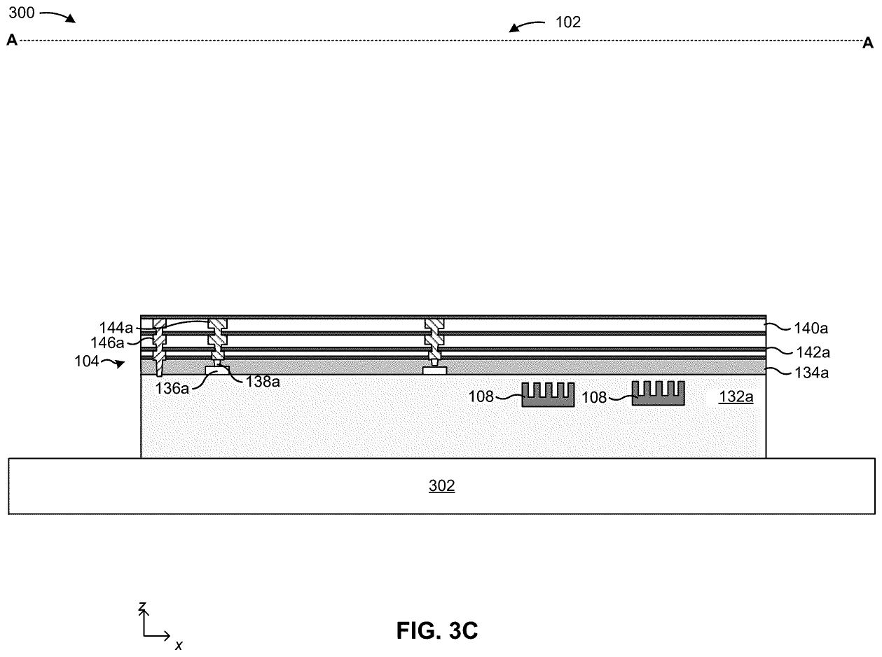

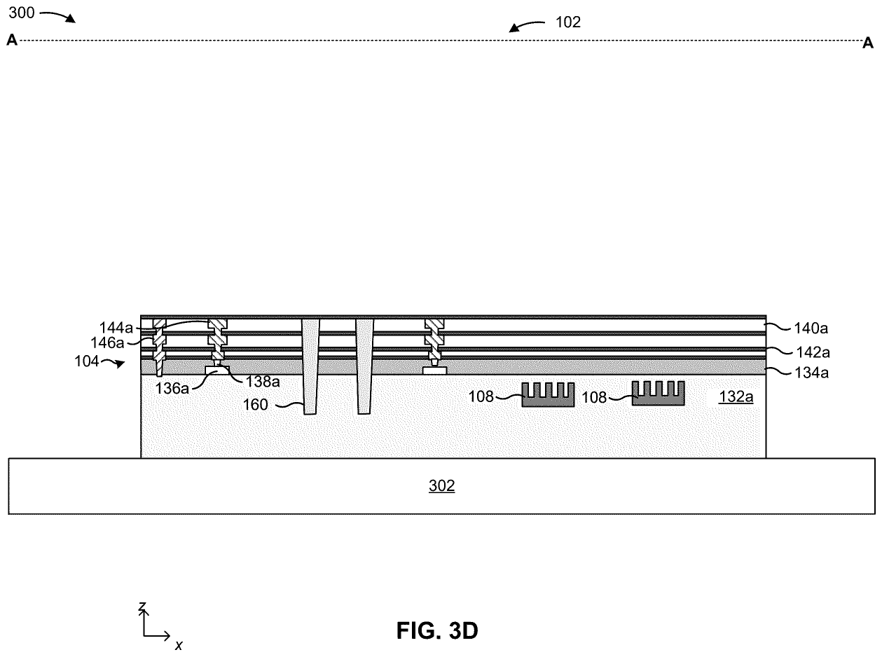

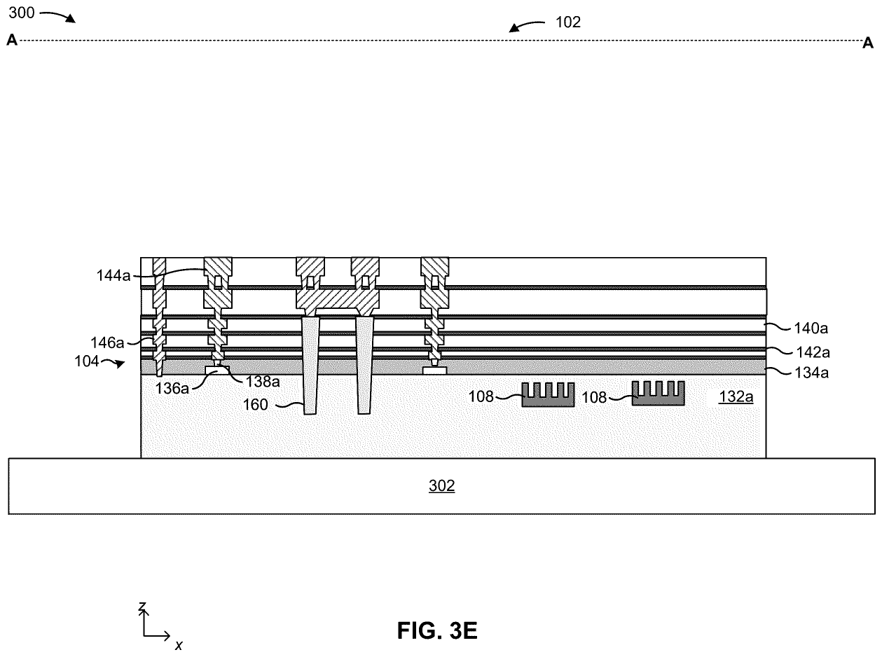

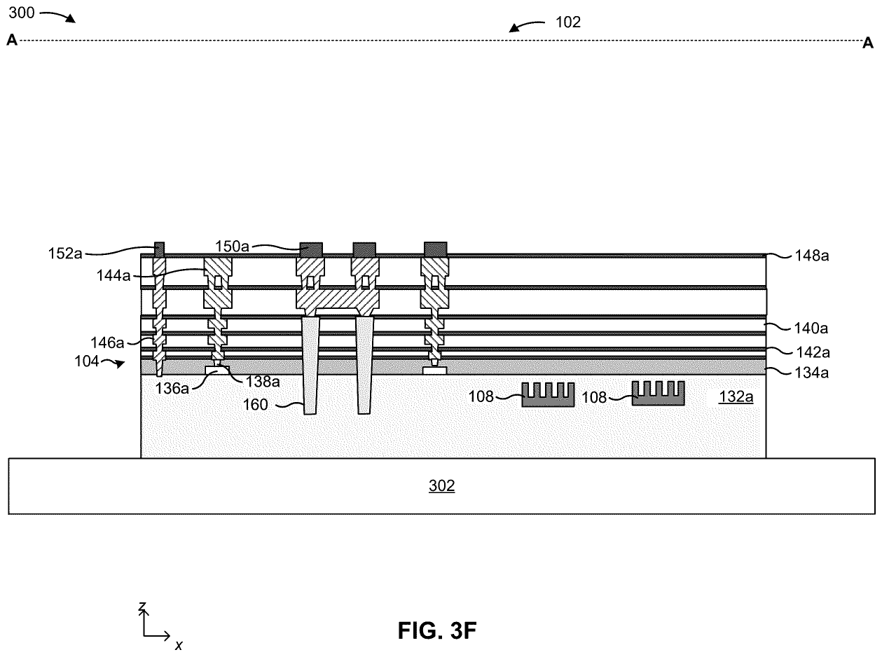

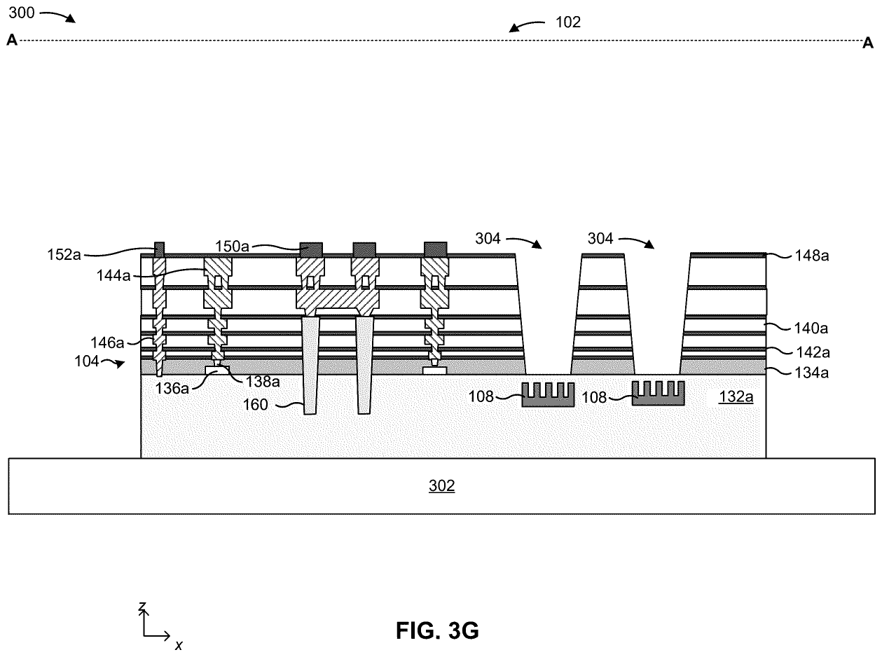

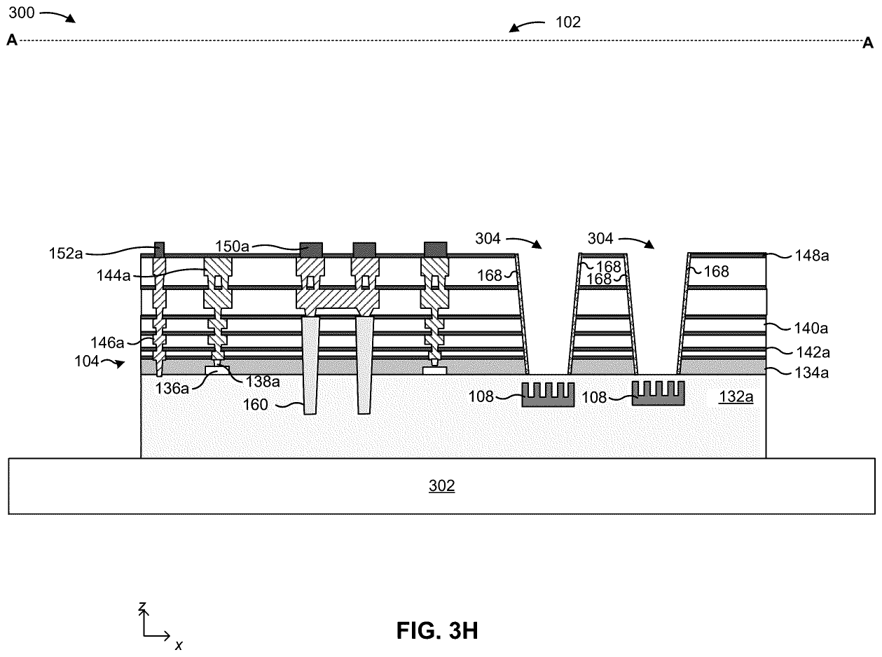

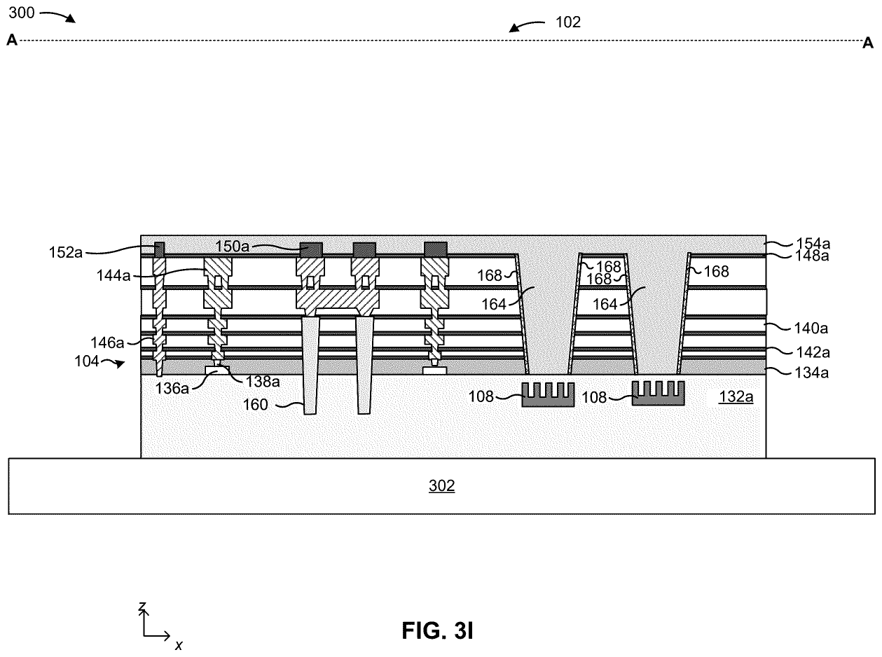

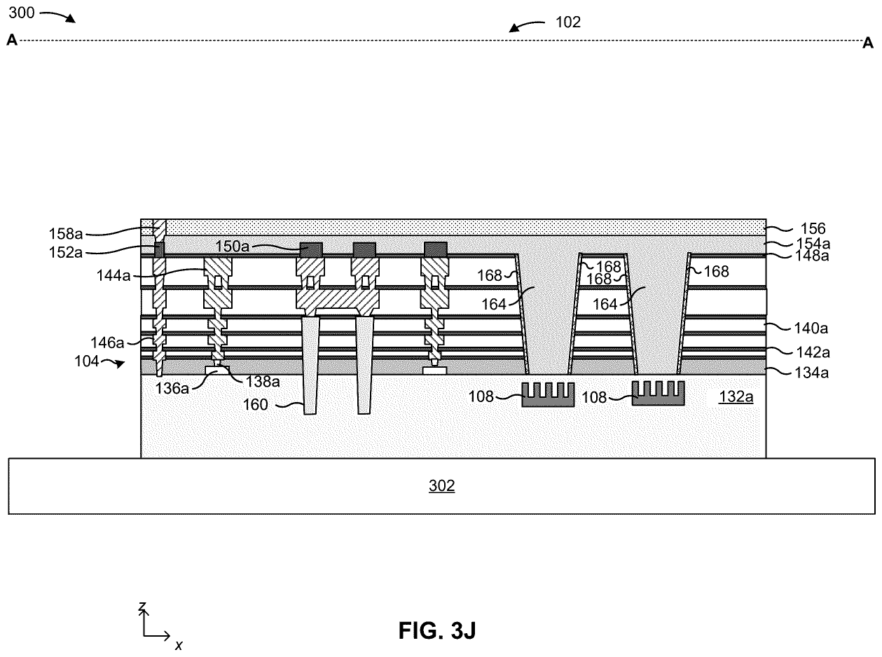

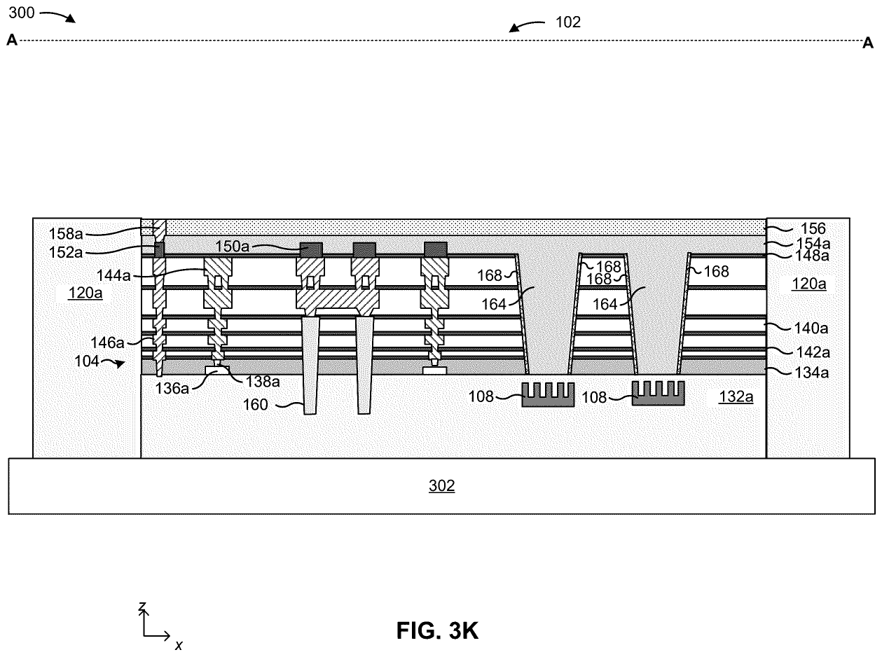

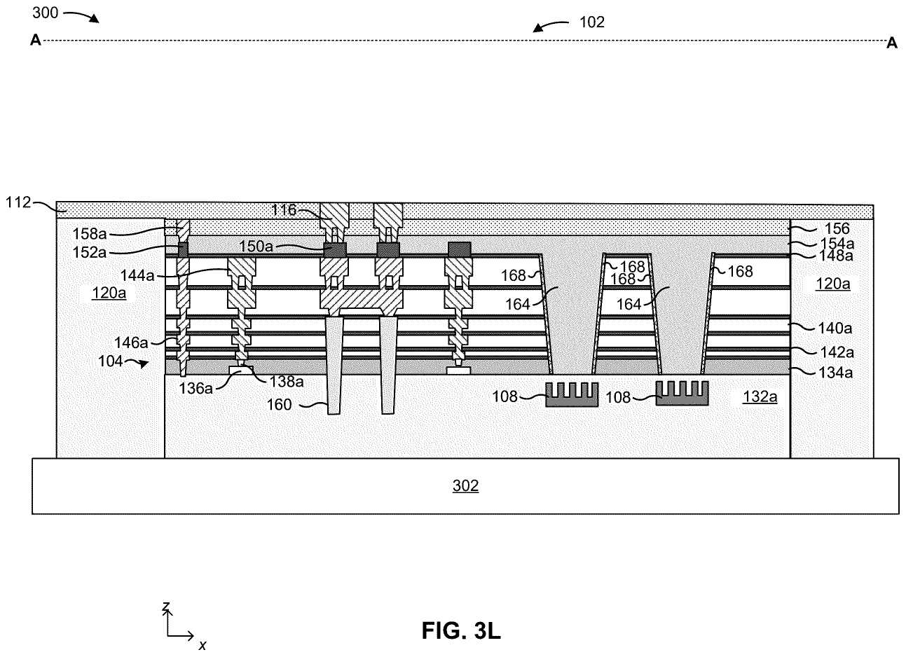

FIGS. 3A-3L are diagrams of an example implementation 300 of forming an IC die 104 described herein. While the processing operations of the example implementation 300 are illustrated and described in connection with forming the IC die 104 described herein, one or more of the processing operations of the example implementation 300 may be performed to form another IC die described herein, such as the IC die 106. In some implementations, one or more of the semiconductor processing operations described in connection with FIGS. 3A-3L may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

Turning to FIG. 3A, the substrate 132a of the IC die 104 is provided. The substrate 132a may be provided in the form of a semiconductor wafer such as a silicon (Si) wafer, may be provided as an SOI wafer, and/or another type of semiconductor work piece. In some implementations, the IC die 104 may be placed on a carrier substrate 302 for processing.

Alternatively, the substrate 132a is used as the carrier for the IC die 104.

As shown in FIG. 3B, the IC devices 136a may be formed in and/or on the substrate 132a of the IC die 104. One or more semiconductor processing tools may be used to form one or more portions of the IC devices 136a. For example, a deposition tool may be used to perform various deposition operations to deposit layers and/or structures of the IC devices 136a, and/or to deposit photoresist layers for etching the substrate 132a and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 132a and/or portions of the deposited layers to form the IC devices 136a. As another example, a planarization tool may be used to planarize portions of the IC devices 136a. As another example, a plating tool may be used to deposit metal structures and/or layers of the IC devices 136a.

As shown in FIG. 3B, the grating couplers 108 may be formed in and/or on the substrate 132a of the IC die 104. One or more semiconductor processing tools may be used to form the grating couplers 108. For example, a patterning layer may be formed (e.g., using a deposition tool) over a semiconductor layer (e.g., a silicon (Si) layer, a germanium (Ge) layer) of the substrate 132a and used to etch (e.g., using an etch tool) to form the grating coupler 108 from the semiconductor layer. Alternatively, a recess may be formed in the substrate 132a (e.g., using an etch tool) and a deposition tool may be used to deposit (e.g., by epitaxy, by chemical vapor deposition (CVD)) the material of grating coupler 108 in the recess. The material may be etched to define the gratings of the grating coupler 108. The dielectric layer 174 may be deposited over the grating couplers 108.

As further shown in FIG. 3B, a deposition tool is used to deposit the ILD layer 134a over and/or on the substrate 132a, over and/or on the IC devices 136a, and/or over and/or on the grating couplers 108. A deposition tool may be used to deposit the ILD layer 134a using a physical vapor deposition (PVD) technique, an atomic layer deposition (ALD) technique, a CVD technique, an oxidation technique, and/or another suitable deposition technique. In some implementations, a planarization tool may be used to perform a planarization operation such as a chemical mechanical planarization (CMP) operation to planarize the ILD layer 134a after the ILD layer 134a is deposited.

As further shown in FIG. 3B, the contacts 138a of the IC devices 136a may be formed through the ILD layer 134a. The contacts 138a may be formed in recesses in the ILD layer 134a. In some implementations, a pattern in a photoresist layer is used to etch the ILD layer 134a to form the recesses. In these implementations, a deposition tool may be used to form the photoresist layer on the ILD layer 134a. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 134a based on a pattern to form the recesses.

A deposition tool may be used to deposit the material of the contacts 138a in the recesses using a CVD technique, a PVD technique, an ALD technique, an electroplating technique, and/or another suitable deposition technique. The material of the contacts 138a may be deposited in one or more deposition operations. In some implementations, a seed layer is first deposited, and the material of the contacts 138a is deposited on the seed layer. In some implementations, a planarization tool is used to perform a planarization operation (e.g., a CMP operation) to planarize the contacts 138a after the contacts 138a are deposited such that the tops of the contacts 138a are approximately co-planar with the top of the ILD layer 134a.

As shown in FIG. 3C, a first portion of the interconnect layer of the IC die 104 is formed above the ILD layer 134a. One or more deposition tools are used to deposit alternating layers of ILD layers 140a and ESLs 142a in the first portion of the interconnect layer of the IC die 104. In this way, the ILD layers 140a and ESLs 142a may be arranged in the z-direction in the IC die 104. One or more deposition tools may be used to deposit each of the ILD layers 140a and each of the ESLs 142a using a PVD technique, an ALD technique, a CVD technique, an oxidation technique, and/or another suitable deposition technique. In some implementations, a planarization tool may be used to planarize the ILD layers 140a and/or the ESLs 142a after the ILD layers 140a and/or the ESLs 142a are deposited.

As further shown in FIG. 3C, a deposition tool, an exposure tool, a developer tool, an etch tool, a planarization tool, a plating tool, and/or another semiconductor processing tool may be used to perform various operations to form the conductive structures 144a and a first portion of the seal ring structure 146a in the first portion of the interconnect layer of the IC die 104. The conductive structures 144a and the first portion of the seal ring structure 146a may be included in the ILD layers 140a and/or the ESLs 142a.

The conductive structures 144a and the first portion of the seal ring structure 146a may be formed in recesses in one or more ILD layers 140a and/or in one or more ESLs 142a. In some implementations, a pattern in a photoresist layer is used to etch the ILD layers 140a and ESLs 142a to form the recesses. In these implementations, a deposition tool may be used to form the photoresist layer on the topmost ILD layer 140a. An exposure tool may be used to expose the photoresist layer to a radiation source to pattern the photoresist layer. A developer tool may be used to develop and remove portions of the photoresist layer to expose the pattern. An etch tool may be used to etch the ILD layers 140a and ESLs 142a based on the pattern to form the recesses. In some implementations, the etch operation includes dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layers 140a and ESLs 142a based on a pattern to form the recesses.

A deposition tool may be used to deposit the material of the conductive structures 144a and the first portion of the seal ring structure 146a in the recesses using a CVD technique, a PVD technique, an ALD technique, an electroplating technique, and/or another suitable deposition technique. The material of the conductive structures 144a and the first portion of the seal ring structure 146a may be deposited in one or more deposition operations. In some implementations, a seed layer is first deposited, and the material of the conductive structures 144a and the first portion of the seal ring structure 146a is deposited on the seed layer. In some implementations, a planarization tool is used to perform a planarization operation (e.g., a CMP operation) to planarize the conductive structures 144a and the first portion of the seal ring structure 146a.

As shown in FIG. 3D, the through-substrate interconnect structure 160 is formed through the first portion of the interconnect layer and into the substrate 132a. To form the through-substrate interconnect structure 160, a recess is formed through the first portion of the interconnect layer and into a portion of the substrate 132a.

In some implementations, a pattern in a photoresist layer is used to etch the ILD layers 140a and the ESLs 142a of the first portion of the interconnect layer, the ILD layer 134a, and the substrate 132a to form the recess. In these implementations, a deposition tool may be used to form the photoresist layer on the topmost ESL 142a. An exposure tool may be used to expose the photoresist layer to a radiation source to pattern the photoresist layer. A developer tool may be used to develop and remove portions of the photoresist layer to expose the pattern. An etch tool may be used to etch the ILD layers 140a and the ESLs 142a of the first portion of the interconnect layer, the ILD layer 134a, and the substrate 132a based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess based on a pattern.

A deposition tool may be used to deposit the through-substrate interconnect structure 160 using a CVD technique, a PVD technique, an ALD technique, an electroplating technique, and/or another suitable deposition technique. The through-substrate interconnect structure 160 may be deposited in one or more deposition operations. In some implementations, a seed layer is first deposited, and the through-substrate interconnect structure 160 is deposited on the seed layer. In some implementations, one or more liners (e.g., a barrier liner, an adhesion liner) may first be deposited in the recess, and the through-substrate interconnect structure 160 may be deposited on the one or more liners in the recess. In some implementations, a planarization tool is used to perform a planarization operation (e.g., a CMP operation) to planarize the through-substrate interconnect structure 160 after the through-substrate interconnect structure 160 is deposited.

As shown in FIG. 3E, a second portion of the interconnect layer of the IC die 104 may be formed. Forming the second portion of the interconnect layer may include forming additional ILD layers 140a, additional ESLs 142a, additional conductive structures 144a, and/or additional portions of the seal ring structure 146a in a similar manner as described in connection with FIG. 3C.

As shown in FIG. 3F, the passivation layer 148a may be deposited, the metal pad structures 150a may be formed on one or more of the conductive structures 144a, and one or more metal pad structures 152a may be formed on the seal ring structure 146a.

In some implementations, a deposition tool may be used to deposit a layer of the electrically conductive material for the metal pad structures 150a and 152a using a CVD technique, a PVD technique, an ALD technique, an electroplating technique, and/or another suitable deposition technique. The a patterning layer may be used to etch the layer of the electrically conductive material to define the metal pad structures 150a and 152a. Alternatively, a patterning layer may be deposited, recesses may be formed in the patterning layer, the material of the metal pad structures 150a and 152a may be deposited in the recesses, and the patterning layer may be subsequently removed. A deposition tool may be used to deposit the passivation layer 148a using a CVD technique, a PVD technique, an ALD technique, an oxidation technique, and/or another suitable deposition technique.

As shown in FIG. 3G, one or more recesses 304 may be formed in the IC die 104. For example, a recess 304 may be formed over a grating coupler 108. A recess 304 may be formed through (and may extend through), the passivation layer 148a, the ILD layers 140a, the ESLs 142a, and/or the ILD layer 134a. In some implementations, a recess 304 partially extends into the substrate 132a. In some implementations, the recess 304 extend into, but not through, the ILD layer 134a. In these implementations, a portion of the ILD layer 134a remains between the bottom of the recess 304 and the substrate 132a.

In some implementations, a pattern in a photoresist layer is used to etch the passivation layer 148a, the ILD layers 140a, the ESLs 142a, and/or the ILD layer 134a to form the recesses 304. In these implementations, a deposition tool may be used to form the photoresist layer on the passivation layer 148a (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the passivation layer 148a, the ILD layers 140a, the ESLs 142a, and/or the ILD layer 134a based on the pattern to form the recesses 304. In some implementations, the etch operation includes a dry etch operation (e.g., a plasma-based etch operation, a gas-based etch operation), a wet chemical etch operation, and/or another type of etch operation. The etch operation may be performed such that the passivation layer 148a, the ILD layers 140a, the ESLs 142a, and/or the ILD layer 134a are etched to form non-vertical (or tapered) sidewalls for the recesses 304. In other words, the top width (e.g., dimension D2) of the recesses 304 is greater than the bottom width (e.g., dimension D1) of the recesses 304, resulting in a tapered profile for the recesses 304. In some implementations, a photoresist removal tool may be used to remove the remaining portions of the photoresist layer (e.g., using a chemical stripper, plasma ashing, and/or another technique).

As shown in FIG. 3H, reflector structures 168 are formed on the sidewalls of the recesses 304. In some implementations, a reflector structure 168 is also formed on the bottom surface of a recesses 304 and is subsequently etched to remove the portion of the reflector structure 168 from the bottom surface of the recess 304 so that the this portion does not interfere with the transmission of optical signals to the underlying grating coupler 108.

A deposition tool may be used to conformally deposit the reflector structures 168 using a CVD technique and/or an ALD technique. In this way, the reflector structures 168 may conform to the profile of the sidewalls of the recesses 304 such that a reflector structure 168 formed in a recess 304 is non-vertical and instead is angled away (e.g., angled away from a bottom of the recess 304 to a top of the recess 304) from the grating coupler 108 underlying the recess 304. In some implementations, another deposition technique such as a PVD technique and/or an electroplating technique are used to deposit the reflector structures 168.

In some implementations, a liner is first deposited on the sidewalls of the recesses 304, and the reflector structures 168 are deposited on the liner. The liner may include a barrier liner, an adhesion liner, and/or another type of liner, and may include materials such as tantalum nitride (TaN) and/or titanium nitride (TiN), among other examples.

As shown in FIG. 3I, the remaining areas in the recesses 304 are filled in with the material of the passivation layer 154a to form dielectric plugs 164 in the recesses 304. The dielectric plugs 164 are formed on the reflector structures 168 in the recesses 304 such that the reflector structures 168 are located between the sidewalls of the dielectric plugs 164 and the surrounding dielectric layers (e.g., the passivation layer 148a, the ILD layers 140a, the ESLs 142a, and/or the ILD layer 134a). The material is deposited above the recesses 304 as well to form the passivation layer 154a above the dielectric plugs 164. The passivation layer 154a may cover the metal pad structures 150a and/or 152a.

A deposition tool may be used to deposit the dielectric material of the passivation layer 154a and of the dielectric plugs 164 using a PVD technique, an ALD technique, a CVD technique, an oxidation technique, and/or another suitable deposition technique. The dielectric material of the passivation layer 154a and of the dielectric plugs 164 may be deposited in one or more deposition operations. In some implementations, a planarization tool may be used to perform a planarization operation (e.g., a CMP operation) to planarize the passivation layer 154a after the passivation layer 154a is deposited.

As shown in FIG. 3J, the dielectric layer 156 a may be deposited over the IC die 104. A deposition tool may be used to deposit the dielectric layer 156a using a PVD technique, an ALD technique, a CVD technique, an oxidation technique, and/or another suitable deposition technique. The dielectric layer 156a may be deposited in one or more deposition operations. In some implementations, a planarization tool may be used to perform a planarization operation (e.g., a CMP operation) to planarize the dielectric layer 156a after the dielectric layer 156a is deposited.

As shown in FIG. 3K, areas around the IC die 104 may be filled in with the dielectric fill layer 120a. A deposition tool may be used to deposit the dielectric fill layer 120a using a PVD technique, an ALD technique, a CVD technique, an oxidation technique, and/or another suitable deposition technique. The dielectric fill layer 120a may be deposited in one or more deposition operations. In some implementations, a planarization tool may be used to perform a planarization operation (e.g., a CMP operation) to planarize the IC die 104 after the dielectric fill layer 120a is deposited.

As shown in FIG. 3L, the bonding dielectric layer 112 may be formed over and/or on the IC die 104 (including over and/or on the dielectric layer 156a, and/or over and/or on the dielectric fill layer 120a). Bonding structures 116 may be formed on the IC die 104. The bonding structures 116 may land on, and may be electrically coupled to, one or more metal pad structures 150a.

A deposition tool may be used to deposit the bonding dielectric layer 112 using a PVD technique, an ALD technique, a CVD technique, an oxidation technique, and/or another suitable deposition technique. In some implementations, a planarization tool may be used to perform a planarization operation (e.g., a CMP operation) to planarize the bonding dielectric layer 112 after the bonding dielectric layer 112 is deposited.

A deposition tool may be used to deposit the bonding structures 116 using a PVD technique, an ALD technique, a CVD technique, an electroplating technique, and/or another suitable deposition technique. In some implementations, a liner is first deposited, and the bonding structures 116 are deposited on the liner. The liner may include a barrier liner, an adhesion liner, and/or another type of liner, and may include materials such as tantalum nitride (TaN) and/or titanium nitride (TiN), among other examples.

In some implementations, the bonding dielectric layer 112 is deposited first, recesses are formed through the bonding dielectric layer 112, through the dielectric layer 156a, and to one or more underlying metal pad structures 150a, and the bonding structures 116 are formed in the recesses. In some implementations, the bonding structures 116 are formed first, and the bonding dielectric layer 112 is formed around the bonding structures 116.

As indicated above, FIGS. 3A-3L are provided as an example. Other examples may differ from what is described with regard to FIGS. 3A-3L.

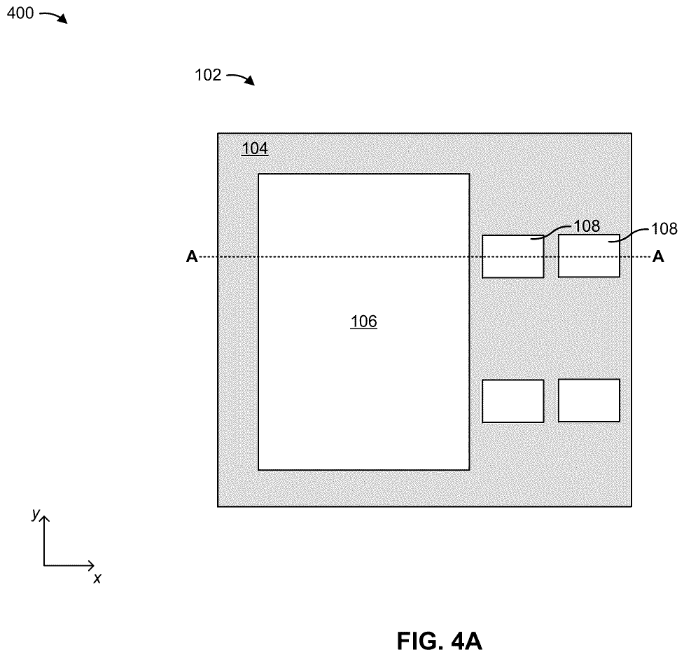

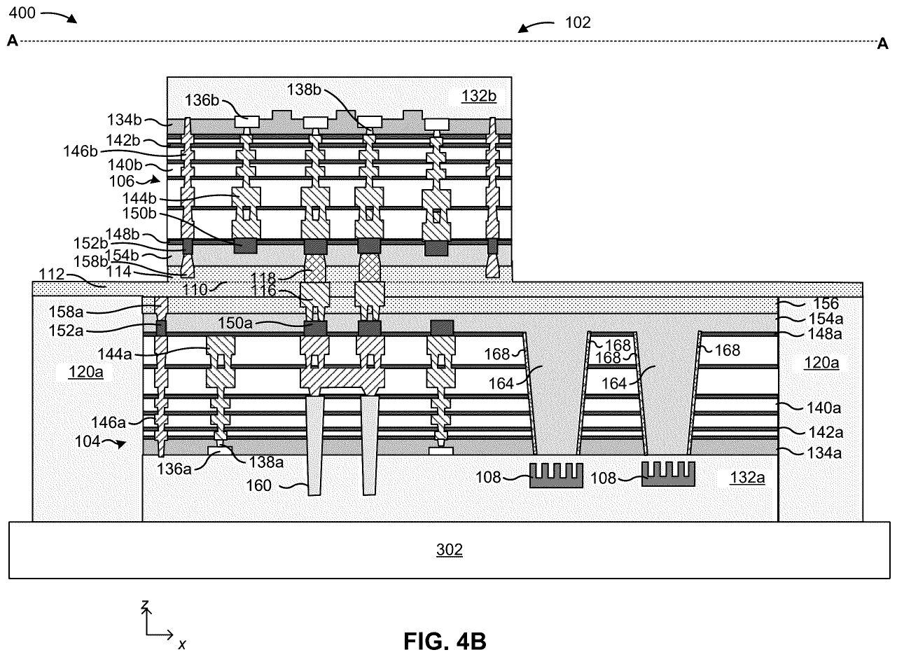

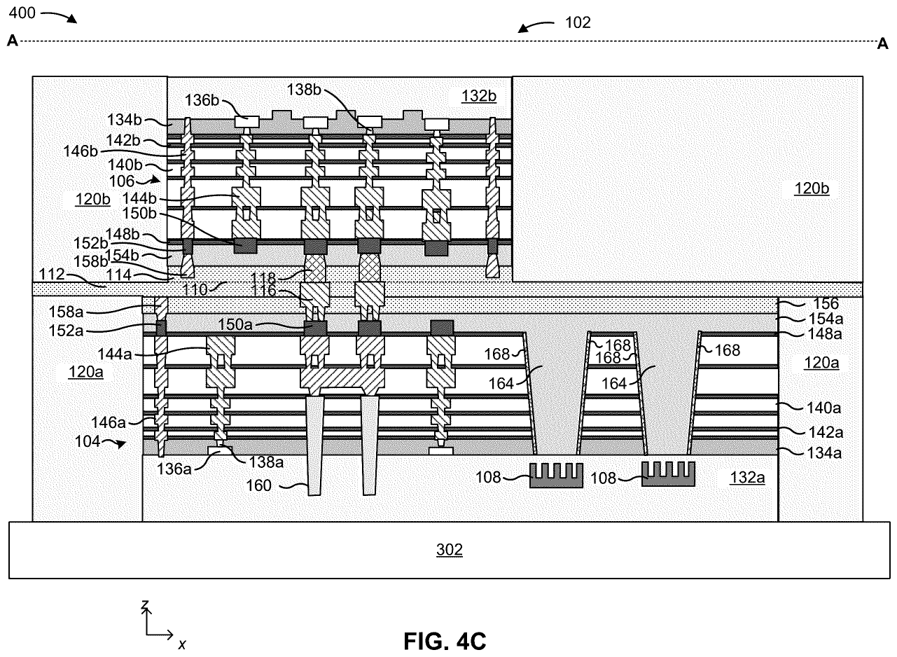

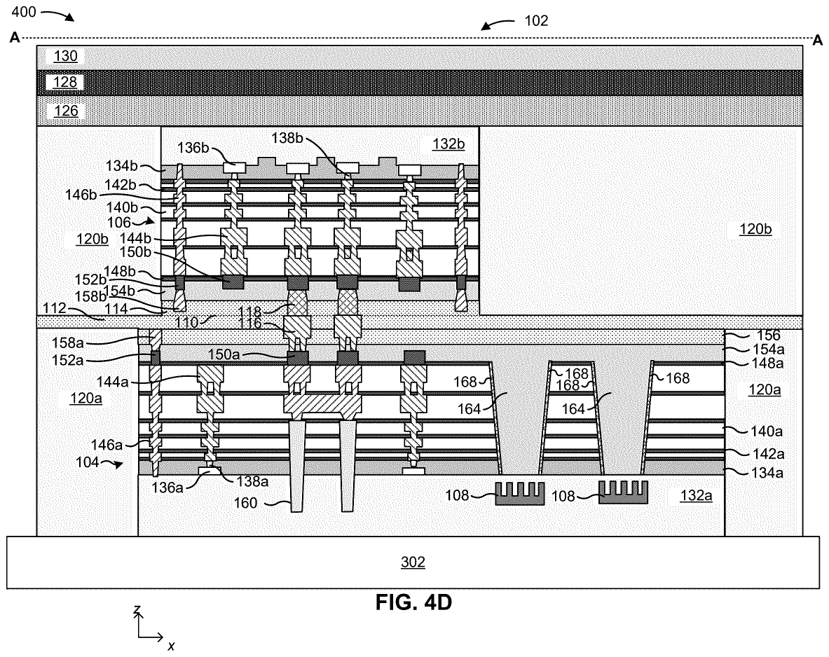

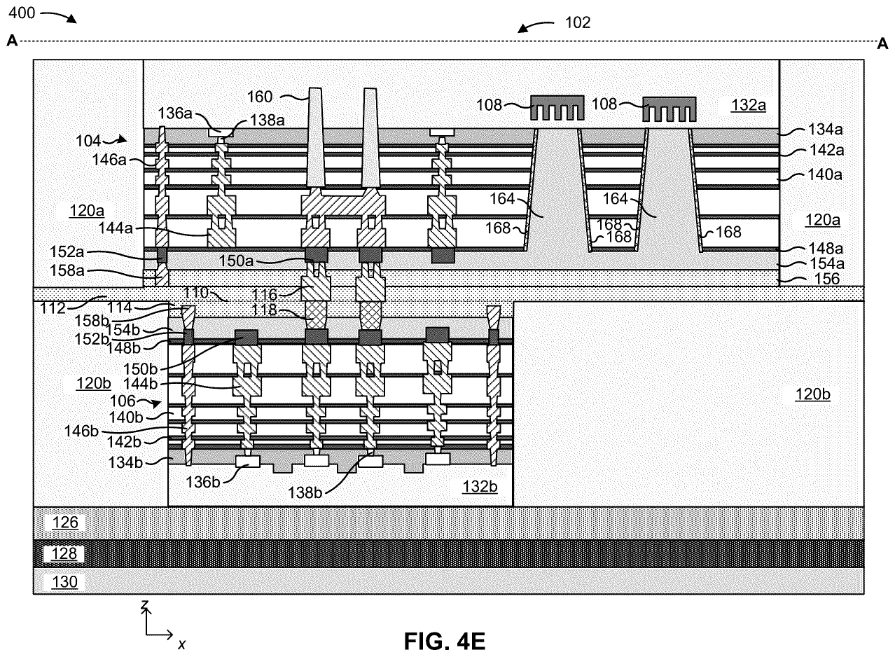

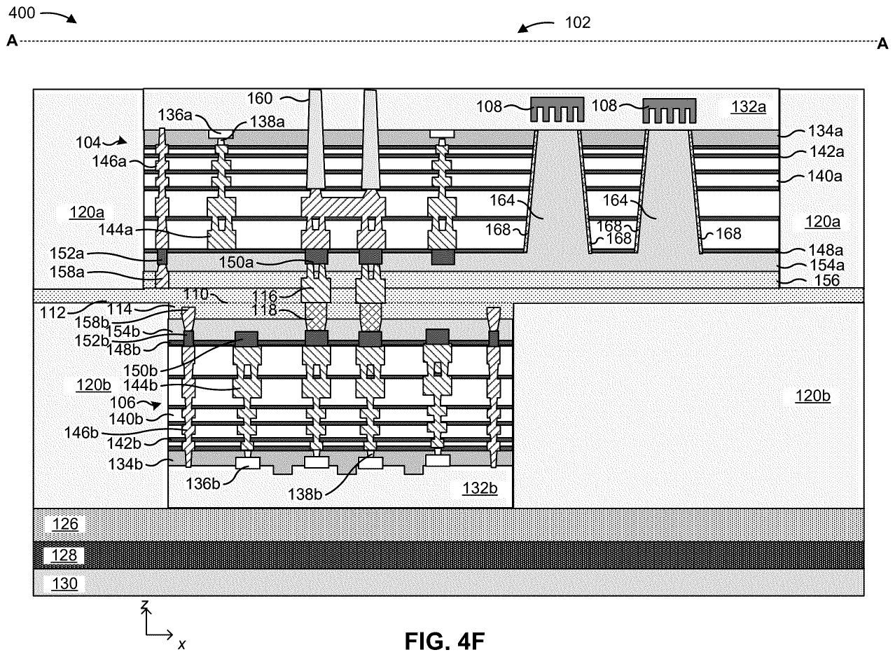

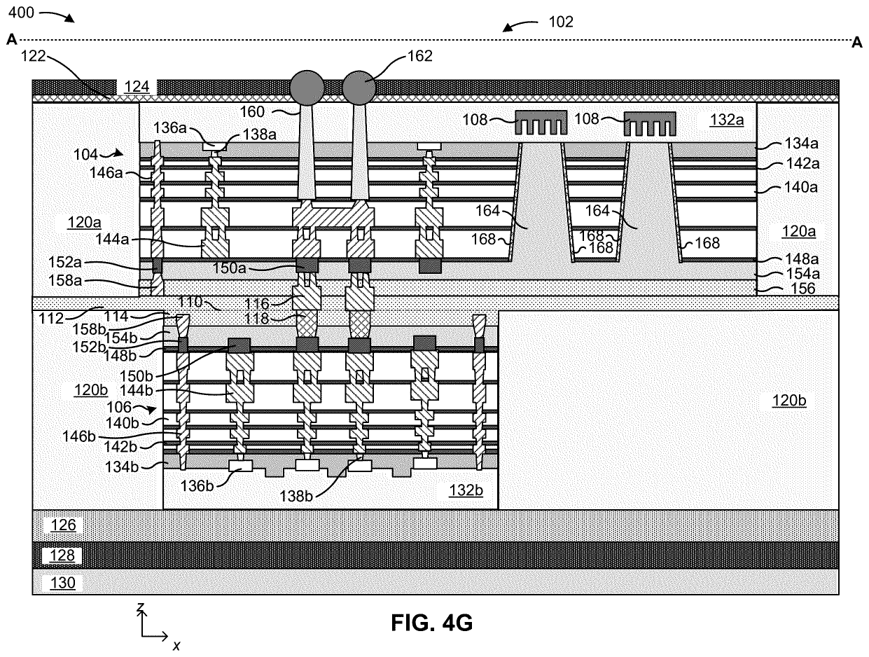

FIGS. 4A-4G are diagrams of an example implementation 400 of forming a device package 102 described herein. In some implementations, one or more of the semiconductor processing operations described in connection with FIGS. 4A-4G may be performed using one or more semiconductor processing tools, such as a deposition tool, an exposure tool, a developer tool, an etch tool, a planarization tool, an ion implantation tool, an annealing tool, a bonding tool, a wafer/die transport tool, and/or another type of semiconductor processing tool.

As shown in FIGS. 4A and 4B, the IC die 106 is bonded to the IC die 104 such that the IC die 104 and the IC die 106 are stacked and vertically arranged (e.g., in the z-direction) in the device package 102. The IC dies 104 and 106 may be bonded at a bonding interface 110.

In some implementations, a bonding tool is used to bond the IC die 104 and the IC die 106 by forming dielectric-to-dielectric bonds between bonding dielectric layer 112 on the IC die 104 and the bonding dielectric layer 114 on the IC die 106. In some implementations, a bonding tool is used to bond the IC die 104 and the IC die 106 by forming metal-to-metal bonds between the bonding structures 116 of the IC die 104 and the bonding structures 118 of the IC die 106. In some implementations, a bonding tool is used to bond the IC die 104 and the IC die 106 by forming a combination of dielectric-to-dielectric bonds and metal-to-metal bonds. In some implementations, a bonding tool is used to bond the IC die 104 and the IC die 106 by forming dielectric-to-metal bonds between the IC dies 104 and 106.

The IC die 106 may be laterally positioned (e.g., in the x-direction, in the y-direction) over the IC die 104 such that the portion of the IC die 104 in which the grating couplers 108 and the associated dielectric plugs 164 and reflector structures 168 are located extends laterally outward from the IC die 106. In other words, the IC die 106 may be laterally positioned over the IC die 104 such that the IC die 106 is not located over the portion of the IC die 104 in which the grating couplers 108 and the associated dielectric plugs 164 and reflector structures 168 are located. This provides an unobstructed light propagation path for optical signals to the IC die 104.

As shown in FIG. 4C, areas around the IC die 106, including the area above the portion of the IC die 104 in which the grating couplers 108 and the associated dielectric plugs 164 and reflector structures 168 are located, are filled with the dielectric fill layer 120b. A deposition tool may be used to deposit the dielectric fill layer 120b using a PVD technique, an ALD technique, a CVD technique, an oxidation technique, and/or another suitable deposition technique. The dielectric fill layer 120b may be deposited in one or more deposition operations. A planarization tool may be used to perform a planarization operation (e.g., a CMP operation) to planarize the dielectric fill layer 120b and/or the substrate 132b of the IC die 106 such that the dielectric fill layer 120b and the substrate 132b of the IC die 106 are approximately co-planar.

As shown in FIG. 4D, the passivation layers 126-130 are formed or provided above the IC die 106. A deposition tool may be used to deposit the passivation layers 126-130 using a PVD technique, an ALD technique, a CVD technique, an oxidation technique, and/or another suitable deposition technique. The passivation layers 126-130 may be deposited in one or more deposition operations. In some implementations, a planarization tool may be used to perform a planarization operation (e.g., a CMP operation) to planarize the passivation layers 126-130 after the passivation layers 126-130 are deposited. Additionally and/or alternatively, one or more of the passivation layers 126-130 may be dispensed onto the IC die 106. Additionally and/or alternatively, the passivation layers 126-130 may be laminated onto or bonded to the device package 102.

As shown in FIG. 4E, the device package 102 is flipped and one or more operations may be performed to remove the carrier substrate 302 (if used) from the device package 102. In some implementations, the carrier substrate 302 is de-bonded from the device package 102 by a thermal operation to alter the adhesive properties of bonding layers that were used to bond the device package 102 to the carrier substrate 302. An energy source such as an ultraviolet (UV) laser, a carbon dioxide (CO2) laser, or an infrared (IR) laser, among other examples, is utilized to irradiate and heat the bonding layers until the adhesive properties of the bonding layer are reduced. Then, the carrier substrate 302 and the bonding layers are physically separated and removed from the device package 102. Additionally and/or alternatively, the carrier substrate 302 and/or the bonding layers may be removed by etching and/or planarization.

As shown in FIG. 4F, a planarization tool or wafer grinding tool may be used to perform a planarization operation (e.g., a CMP operation, a wafer grinding operation) to remove material from the back side of the substrate 132a of the IC die 104 such that the through-substrate interconnect structure(s) 160 are exposed through the back side of the substrate 132a.

As shown in FIG. 4G, the passivation layers 122 and 124 are formed on the back side of the substrate 132a of the IC die 104. A deposition tool may be used to deposit the passivation layers 122 and 124 using a PVD technique, an ALD technique, a CVD technique, an oxidation technique, and/or another suitable deposition technique. The passivation layers 122 and 124 may be deposited in one or more deposition operations. In some implementations, a planarization tool may be used to perform a planarization operation (e.g., a CMP operation) to planarize the passivation layers 122 and 124 after the passivation layers 122 and 124 are deposited.

Additionally and/or alternatively, passivation layers 122 and 124 may be dispensed onto the IC die 104. The connection structures 162 may also be attached to the device package 102 such that the connection structures 162 are electrically coupled to the through-substrate interconnect structure(s) 160.

As indicated above, FIGS. 4A-4G are provided as an example. Other examples may differ from what is described with regard to FIGS. 4A-4G.

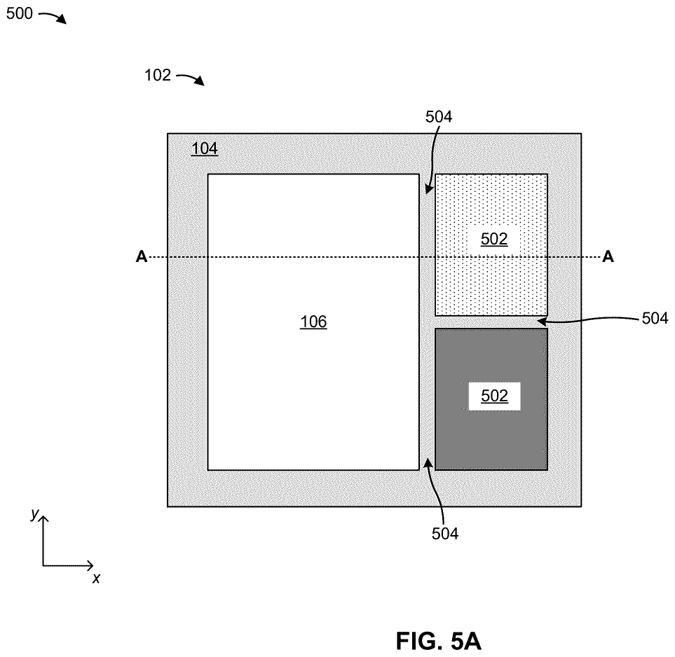

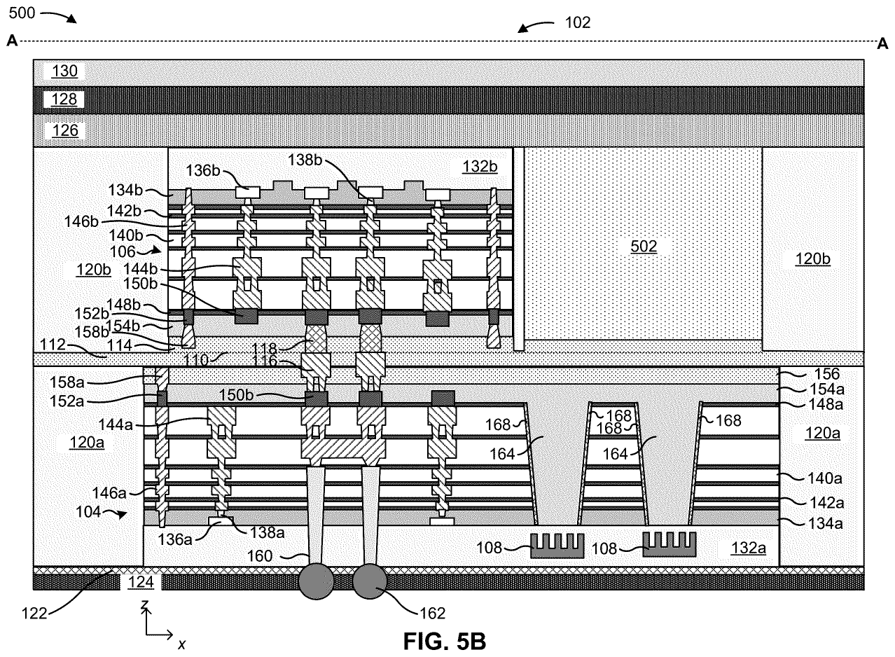

FIGS. 5A and 5B are diagrams of an example implementation 500 of the device package 102 described herein. The example implementation 500 of the device package 102 illustrated in FIGS. 5A and 5B is similar to the example implementation 100 of the device package 102 illustrated in FIGS. 1A-1C, except that one or more non-active dies 502 may be included over and/or on the IC die 104 over regions of the IC die 104 that extend laterally outward from the IC die 106 in the example implementation 500 of the device package 102.

The non-active dies 502 may each include dies that are passive components and/or dies that do not perform electrical and/or processing functions of the device package 102. Examples of non-active dies 502 include dummy dies, integrated passive device (IPD) dies, dielectric structures (e.g., thick films), and/or other types of non-active dies. A non-active die may also be referred to as an insertion die, a filler die, and/or another type of die that does not perform electrical and/or processing functions of the device package 102. An IPD die may include a capacitor or capacitor die, a resistor or resistor die, an inductor or inductor die, or a combination thereof.

The non-active dies 502 and the IC die 106 may be physically touching (e.g., in physical contact with each other), or may be spaced apart by gaps 504 as shown in the top view in FIG. 5A. As shown in the cross-section view along the line A-A in FIG. 5B, a non-active die 502 may be positioned above one or more of the dielectric plugs 164 that are above the grating coupler(s) 108 of the IC die 104. Optical signals may propagate through the non-active die 502 toward the grating coupler(s) 108 through the dielectric plug(s) 164. The reflector structure(s) 168 on the sidewalls of the dielectric plug(s) 164 may increase the confinement of the optical signals as the optical signals propagate through the IC die 104 to the grating coupler(s) 108.

In some implementations, a non-active die 502 is bonded to the bonding dielectric layer 112 of the IC die 104. In some implementations, a non-active die 502 is formed or deposited on the IC die 104. In some implementations, the IC die 104 includes additional bonding structures 116 under the non-active die 502, and the reflector structure(s) 602 are bonded to one or more bonding structures 116 of the IC die 104.

As indicated above, FIGS. 5A and 5B are provided as an example. Other examples may differ from what is described with regard to FIGS. 5A and 5B.

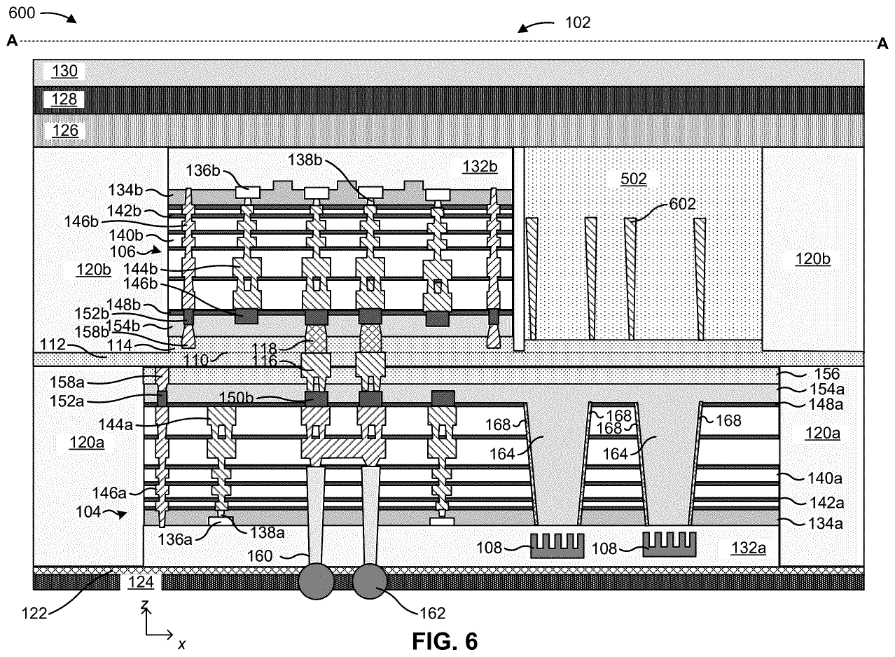

FIG. 6 is a diagram of an example implementation 600 of the device package 102 described herein. As shown in FIG. 6, example implementation 600 of the device package 102 illustrated in FIG. 6 is similar to the example implementation 500 of the device package 102 illustrated in FIGS. 5A and 5B in that one or more non-active dies 502 are included over and/or on the IC die 104.

However, and as shown in FIG. 6, a non-active die 502 in the example implementation 600 of the device package 102 includes one or more reflector structures 602 that extend through at least a portion of the non-active die 502. A reflector structure 602 of the non-active die 502 may be positioned above a reflector structure 168 around a dielectric plug 164 in the IC die 104. In some implementations, a reflector structure 602 may be aligned in the x-direction and/or in the y-direction with a reflector structure 168 such that the reflector structure 602 overlaps the reflector structure 168. In some implementations, a reflector structure 602 may be partially aligned in the x-direction and/or in the y-direction with a reflector structure 168 such that one or more segments or portions of the reflector structure 602 overlaps with one or more segments or portions the reflector structure 168. In some implementations, a reflector structure 602 may be laterally offset in the x-direction and/or in the y-direction relative to a reflector structure 168.

In some implementations, a reflector structure 602 may include a closed-loop structure similar to a reflector structure 168. A reflector structure 602 may be formed by forming a recess in the non-active die 502 and depositing the material of the reflector structure 602 in the recess.

As indicated above, FIG. 6 is provided as an example. Other examples may differ from what is described with regard to FIG. 6.

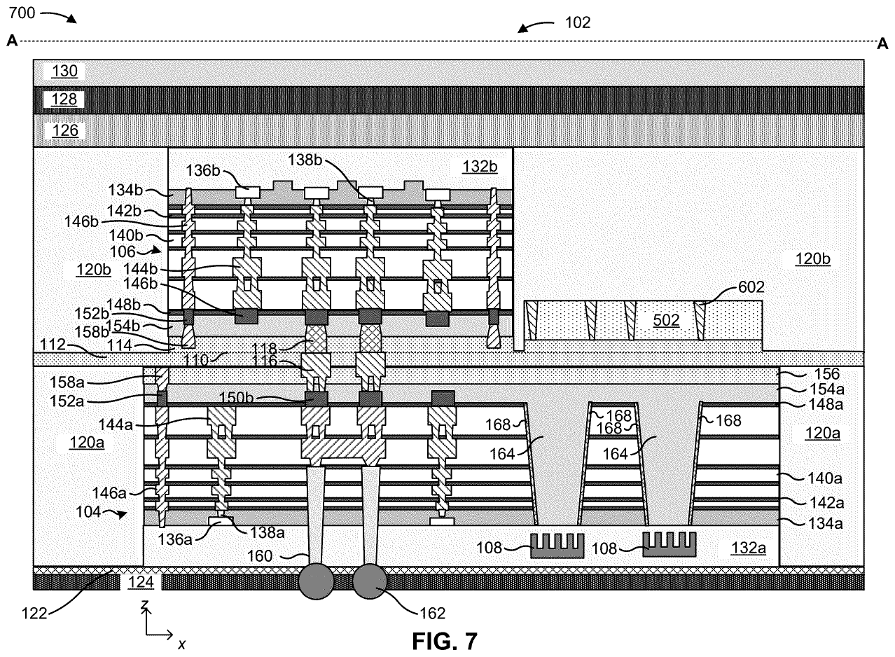

FIG. 7 is a diagram of an example implementation 700 of the device package 102 described herein. As shown in FIG. 7, example implementation 700 of the device package 102 illustrated in FIG. 7 is similar to the example implementation 600 of the device package 102 illustrated in FIG. 6 in that one or more non-active dies 502 are included over and/or on the IC die 104 over regions of the IC die 104, and a non-active die 502 includes one or more reflector structures 602.

However, and as shown in FIG. 7, the reflector structure(s) 602 extend fully through a non-active die 502 in the z-direction in the example implementation 700 of the device package 102. In other words, the tops of the reflector structure(s) 602 may be approximately co-planar with the top of the non-active die 502. Additionally and/or alternatively, as shown in FIG. 7, the z-direction height of the non-active die 502 may be less than the z-direction height of the IC die 106. Thus, the dielectric fill layer 120b may be included on top of the non-active die 502, as well as laterally around the non-active die 502.

As indicated above, FIG. 7 is provided as an example. Other examples may differ from what is described with regard to FIG. 7.

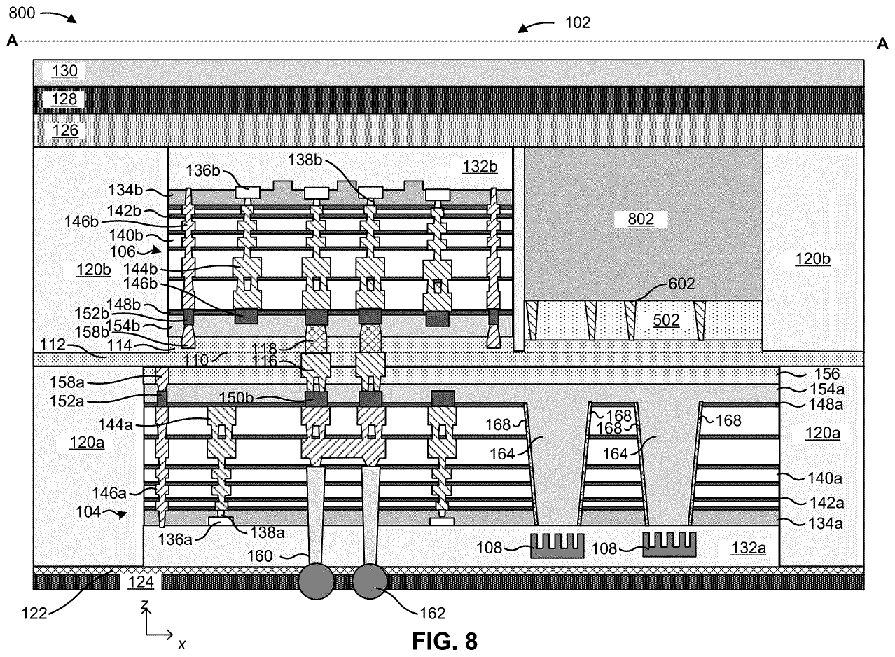

FIG. 8 is a diagram of an example implementation 800 of the device package 102 described herein. As shown in FIG. 8, the example implementation 800 of the device package 102 illustrated in FIG. 8 is similar to the example implementation 700 of the device package 102 illustrated in FIG. 7 in that one or more non-active dies 502 are included over and/or on the IC die 104, and a non-active die 502 includes one or more reflector structures 602.

As further shown in FIG. 8, the example implementation 800 of the device package 102 further includes another non-active die 802 above and/or on the non-active die 502. The non-active dies 502 and 802 may be stacked and vertically arranged in the z-direction in the device package 102. In some implementations, the non-active dies 502 and 802 are bonded together (e.g., in dielectric-to-dielectric bonds, metal-to-dielectric bonds, metal-to-metal bonds). In some implementations, the non-active die 802 is formed on the non-active die 502.

In some implementations, the non-active dies 502 and 802 may include different dielectric materials that enable the refractive indexes of the non-active dies 502 and 802 to be tuned to reduce reflections of optical signals away from the IC die 104. In some implementations, the non-active dies 502 and 802 include the same dielectric material.

As indicated above, FIG. 8 is provided as an example. Other examples may differ from what is described with regard to FIG. 8.

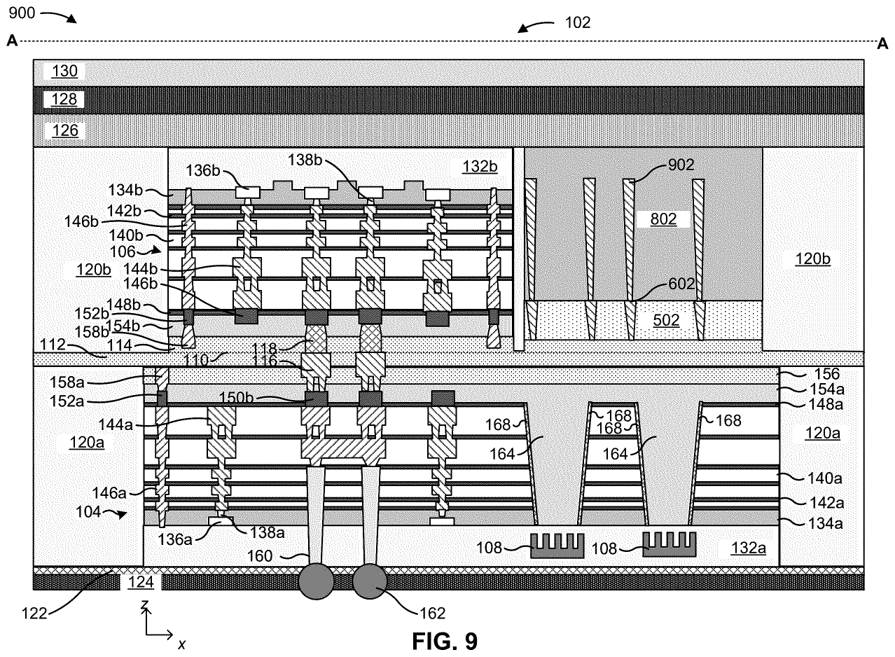

FIG. 9 is a diagram of an example implementation 900 of the device package 102 described herein. As shown in FIG. 9, the example implementation 900 of the device package 102 illustrated in FIG. 9 is similar to the example implementation 800 of the device package 102 illustrated in FIG. 8 in that a non-active die 802 is included on a non-active die 502 over and/or on the IC die 104, and the non-active die 502 includes one or more reflector structures 602.

As further shown in FIG. 9, the example implementation 900 of the device package 102 may further include additional reflector structures 902 in the non-active die 802. A reflector structure 902 may extend through at least a portion of the non-active die 802. A reflector structure 902 of the non-active die 802 may be positioned above a reflector structure 602 in the non-active die 502. In some implementations, a reflector structure 902 may be aligned in the x-direction and/or in the y-direction with a reflector structure 602 such that the reflector structure 902 overlaps the reflector structure 602. In some implementations, a reflector structure 902 may be partially aligned in the x-direction and/or in the y-direction with a reflector structure 602 such that one or more segments or portions of the reflector structure 902 overlaps with one or more segments or portions the reflector structure 602. In some implementations, a reflector structure 902 may be laterally offset in the x-direction and/or in the y-direction relative to a reflector structure 602.

In some implementations, a reflector structure 902 may include a closed-loop structure similar to a reflector structure 168 and/or similar to a reflector structure 602. A reflector structure 902 may be formed by forming a recess in the non-active die 802 and depositing the material of the reflector structure 902 in the recess.

As indicated above, FIG. 9 is provided as an example. Other examples may differ from what is described with regard to FIG. 9.

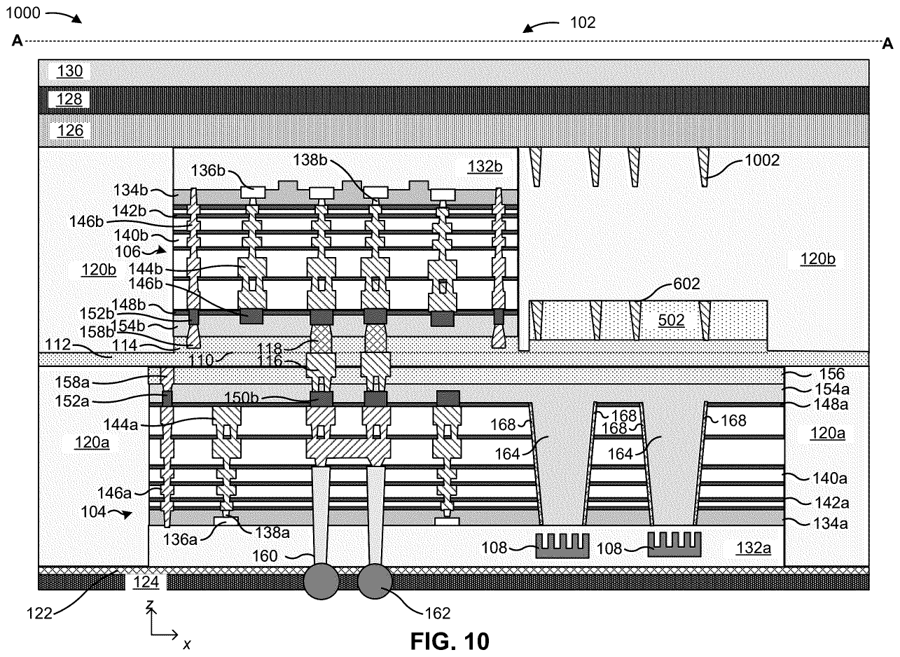

FIG. 10 is a diagram of an example implementation 1000 of the device package 102 described herein. As shown in FIG. 10, the example implementation 1000 of the device package 102 illustrated in FIG. 10 is similar to the example implementation 700 of the device package 102 illustrated in FIG. 7 in that one or more non-active dies 502 are included over and/or on the IC die 104, and a non-active die 502 includes one or more reflector structures 602.

As further shown in FIG. 10, the example implementation 1000 of the device package 102 may further include additional reflector structures 1002 in the dielectric fill layer 120b above the non-active die 502. A reflector structure 1002 may extend through at least a portion of the dielectric fill layer 120b. A reflector structure 1002 may be positioned above a reflector structure 602 in the non-active die 502. In some implementations, a reflector structure 1002 may be aligned in the x-direction and/or in the y-direction with a reflector structure 602 such that the reflector structure 1002 overlaps the reflector structure 602. In some implementations, a reflector structure 1002 may be partially aligned in the x-direction and/or in the y-direction with a reflector structure 602 such that one or more segments or portions of the reflector structure 1002 overlaps with one or more segments or portions the reflector structure 602. In some implementations, a reflector structure 1002 may be laterally offset in the x-direction and/or in the y-direction relative to a reflector structure 602.

In some implementations, a reflector structure 1002 may include a closed-loop structure similar to a reflector structure 168 and/or similar to a reflector structure 602. A reflector structure 1002 may be formed by forming a recess in the dielectric fill layer 120b and depositing the material of the reflector structure 1002 in the recess.

As indicated above, FIG. 10 is provided as an example. Other examples may differ from what is described with regard to FIG. 10.

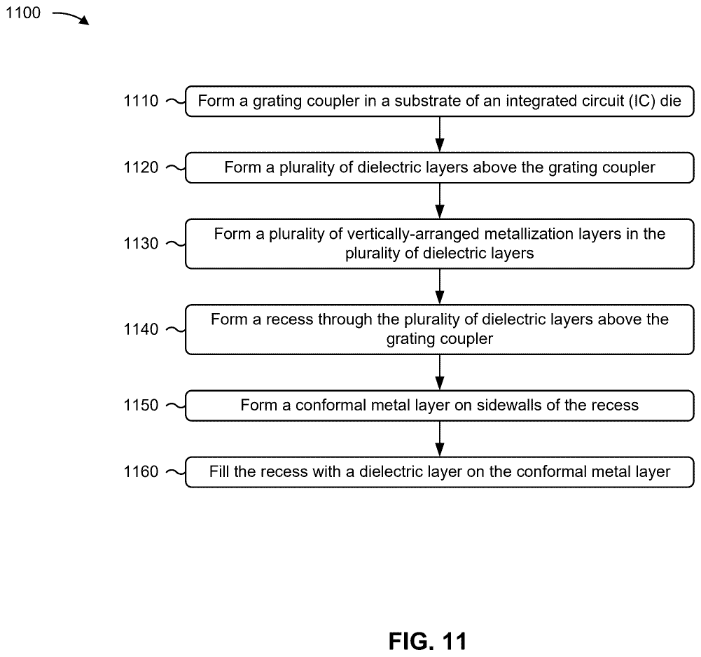

FIG. 11 is a flowchart of an example process 1100 associated with forming a semiconductor device described herein. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a bonding tool, a wafer/die transport tool, and/or another type of semiconductor processing tool.

As shown in FIG. 11, process 1100 may include forming a grating coupler in a substrate of an IC die (block 1110). For example, one or more semiconductor processing tools may be used to form a grating coupler (e.g., a grating coupler 108) in a substrate (e.g., a substrate 132a) of an IC die (e.g., an IC die 106), as described herein.

As further shown in FIG. 11, process 1100 may include forming a plurality of dielectric layers above the grating coupler (block 1120). For example, one or more semiconductor processing tools may be used to form a plurality of dielectric layers (e.g., a dielectric layer 134a, an ILD layer 140a, an ESL 142a, a passivation layer 148a) above the grating coupler, as described herein.

As further shown in FIG. 11, process 1100 may include forming a plurality of vertically-arranged metallization layers in the plurality of dielectric layers (block 1130). For example, one or more semiconductor processing tools may be used to form a plurality of vertically-arranged metallization layers (e.g., conductive structures 144a) in the plurality of dielectric layers, as described herein.

As further shown in FIG. 11, process 1100 may include forming a recess through the plurality of dielectric layers above the grating coupler (block 1140). For example, one or more semiconductor processing tools may be used to form a recess (e.g., a recess 304) through the plurality of dielectric layers above the grating coupler, as described herein.

As further shown in FIG. 11, process 1100 may include forming a conformal metal layer on sidewalls of the recess (block 1150). For example, one or more semiconductor processing tools may be used to form a conformal metal layer (e.g., a reflector structure 168) on sidewalls of the recess, as described herein.

As further shown in FIG. 11, process 1100 may include filling the recess with a dielectric layer on the conformal metal layer (block 1160). For example, one or more semiconductor processing tools may be used to fill the recess with a dielectric layer (e.g., a dielectric plug 164 when forming a passivation layer 154a) on the conformal metal layer, as described herein.

Process 1100 may include additional implementations, such as any single implementation or any combination of implementations described below and/or in connection with one or more other processes described elsewhere herein.

In a first implementation, forming the recess includes forming the recess such that the sidewalls of the recess are tapered between a bottom of the recess and a top of the recess, where the conformal metal layer conforms to an angle (e.g., a dimension D5) of the sidewalls of the recess.

In a second implementation, alone or in combination with the first implementation, a top view shape of the bottom of the recess and a top view shape of the top of the recess are different top view shapes.

In a third implementation, alone or in combination with one or more of the first and second implementations, forming the recess includes forming the recess such that the sidewalls of the recess are approximately vertical between a bottom of the recess and a top of the recess.

In a fourth implementation, alone or in combination with one or more of the first through third implementations, forming the recess includes forming the recess such that a width (e.g., a dimension D1) of a bottom of the recess is greater than a width (e.g., a dimension D3) of the grating coupler.

In a fifth implementation, alone or in combination with one or more of the first through fourth implementations, the conformal metal layer includes at least one of tungsten (W), tantalum nitride (TaN), or titanium nitride (TiN).

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, a semiconductor device includes a grating coupler and a dielectric plug adjacent to the grating coupler. The dielectric plug defines an optical signal path through which optical signals propagate to the grating coupler. To provide increased confinement of optical signals so as to reduce scattering and reduce crosstalk with other optical signals, a reflector structure is included around the perimeter of the dielectric plug. The reflector structure is formed of an optically reflective material such as one or more metal materials. The reflector structure may reduce the likelihood of scattering of the optical signal into the layers of the semiconductor device around the dielectric plug by reflecting the optical signal toward the grating coupler.

Additionally and/or alternatively, the reflector structure may reduce the likelihood of other optical signals interfering with the optical signal by reflecting the other optical signals away from the grating coupler. In this way, the reflector structure reduces scattering of and/or interference with the optical signal, which may reduce the likelihood of and/or the rate of conversion errors when converting the optical signal to an electrical signal.

As described in greater detail above, some implementations described herein provide a device package. The device package includes a first IC die. The device package includes a second IC die bonded to and vertically arranged with the first IC die. The first IC die includes a grating coupler, one or more dielectric layers above the grating coupler, a dielectric plug above the grating coupler and vertically extending through the one or more dielectric layers, and a reflector structure on sidewalls of the dielectric plug.

As described in greater detail above, some implementations described herein provide a device package. The device package includes a first IC die. The device package includes a second IC die bonded to and vertically arranged with the first IC die. The first IC die includes a grating coupler, one or more dielectric layers above the grating coupler, a dielectric plug above the grating coupler and vertically extending through the one or more dielectric layers, and a reflector structure on sidewalls of the dielectric plug. The dielectric plug is located in a region of the first IC die that extends laterally outward from the second IC die. In a top view of the reflector structure, the reflector structure continuously surrounds a top view perimeter of the dielectric plug.

As described in greater detail above, some implementations described herein provide a method. The method includes forming a grating coupler in a substrate of an IC die. The method includes forming a plurality of dielectric layers above the grating coupler. The method includes forming a plurality of vertically-arranged metallization layers in the plurality of dielectric layers. The method includes forming a recess through the plurality of dielectric layers above the grating coupler. The method includes forming a conformal metal layer on sidewalls of the recess. The method includes filling the recess with a dielectric layer on the conformal metal layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device package, comprising:
a first integrated circuit (IC) die; and
a second IC die bonded to and vertically arranged with the first IC die,
wherein the first IC die comprises:
a grating coupler;
one or more dielectric layers above the grating coupler;
a dielectric plug above the grating coupler and vertically extending through the one or more dielectric layers; and
a reflector structure on sidewalls of the dielectric plug.

2. The device package of claim 1, wherein the reflector structure comprises a conformal metal thin film that is located between the dielectric plug and the one or more dielectric layers.

3. The device package of claim 1, wherein the reflector structure comprises a layer of at least one of:
tantalum (Ta),
titanium (Ti),
aluminum (Al), or
copper (Cu).

4. The device package of claim 1, wherein a width of a bottom of the dielectric plug adjacent to the grating coupler is different than a width of a top of the dielectric plug;
wherein the sidewalls of the dielectric plug are angled between the bottom and the top of the dielectric plug; and
wherein the reflector structure conforms to sidewalls of the dielectric plug.

5. The device package of claim 4, wherein a lateral width of the grating coupler is less than the width of the bottom of the dielectric plug.

6. The device package of claim 4, wherein the grating coupler is laterally within a perimeter of the reflector structure.

7. The device package of claim 4, wherein the reflector structure is positioned at an angle relative to a substrate of the second IC die; and
wherein the angle is less than approximately 90 degrees.

8. A device package, comprising:
a first integrated circuit (IC) die; and
a second IC die bonded to and vertically arranged with the first IC die,
wherein the first IC die comprises:
a grating coupler;
one or more dielectric layers above the grating coupler;
a dielectric plug above the grating coupler and vertically extending through the one or more dielectric layers,
wherein the dielectric plug is located in a region of the first IC die that extends laterally outward from the second IC die; and
a reflector structure on sidewalls of the dielectric plug,
wherein, in a top view of the reflector structure, the reflector structure surrounds a top view perimeter of the dielectric plug.

9. The device package of claim 8, wherein the device package further comprises:
a non-active die structure above the region of the first IC die that extends laterally outward from the second IC die,
wherein the non-active die structure is laterally adjacent to the second IC die.

10. The device package of claim 9, wherein the non-active die structure comprises another reflector structure that is located above the reflector structure of the first IC die.

11. The device package of claim 9, wherein the non-active die structure comprises:
a first non-active die bonded to the first IC die; and
a second non-active die bonded to the first non-active die,
wherein the first non-active die is vertically between the second non-active die and the first IC die, and
wherein the first non-active die comprises another reflector structure that is located above the reflector structure of the first IC die.

12. The device package of claim 9, further comprising:
a filler material layer included around the second IC die, around the non-active die, and above the non-active die structure.

13. The device package of claim 12, wherein the reflector structure is a first reflector structure;
wherein the non-active die structure comprises a second reflector structure that is located above the first reflector structure of the first IC die; and
wherein the device package comprises a third reflector structure in the filler material layer above the non-active die structure.

14. The device package of claim 8, further comprising:
a filler material layer included around the second IC die and above the region of the first IC die that extends laterally outward from the second IC die.

15. A method, comprising:
forming a grating coupler in a substrate of an integrated circuit (IC) die;
forming a plurality of dielectric layers above the grating coupler;
forming a plurality of vertically-arranged metallization layers in the plurality of dielectric layers;
forming a recess through the plurality of dielectric layers above the grating coupler;
forming a conformal metal layer on sidewalls of the recess; and
filling the recess with a dielectric layer on the conformal metal layer.

16. The method of claim 15, wherein forming the recess comprises:
forming the recess such that the sidewalls of the recess are tapered between a bottom of the recess and a top of the recess,
wherein the conformal metal layer conforms to an angle of the sidewalls of the recess.

17. The method of claim 16, wherein a top view shape of the bottom of the recess and a top view shape of the top of the recess are different top view shapes.

18. The method of claim 15, wherein forming the recess comprises:
forming the recess such that the sidewalls of the recess are approximately vertical between a bottom of the recess and a top of the recess.

19. The method of claim 15, wherein forming the recess comprises:
forming the recess such that a width of a bottom of the recess is greater than a width of the grating coupler.

20. The method of claim 15, wherein the conformal metal layer comprises at least one of:
tungsten (W),
tantalum nitride (TaN), or
titanium nitride (TIN).
